(19) United States
(12) Patent Application Publication
(10) Pub. No.: US 2026/0023894 A1
(43) Pub. Date: Jan. 22, 2026

(54) INCORPORATING TREES INTO MULTIPLE RESOLUTION MESHES USED IN ENVIRONMENTAL MODELING

(71) Applicant: Arizona Board of Regents on Behalf of Arizona State University, Scottsdale, AZ (US)

(72) Inventors: Enrique Vivoni, Tempe, AZ (US); Giuseppe Mascaro, Tempe, AZ (US); Logan Raming, Salt Lake City, UT (US)

(21) Appl. No.: 19/275,375

(22) Filed: Jul. 21, 2025

Related U.S. Application Data
(60) Provisional application No. 63/674,059, filed on Jul. 22, 2024.

(51) Int. Cl. G06F 30/20

(52) U.S. Cl. CPC G06F 30/20

(57) ABSTRACT

A computer-implemented method facilitates vegetation management and environmental simulation for a geographic region. The method includes obtaining input data representing tree areas and tree characteristics for one or more species. Tree nodes are created based on identified tree centroids from the tree areas. Spatial data structures are generated to represent vegetation and terrain features based on the tree nodes and terrain data. Selection criteria are applied to partition the tree nodes into management categories. Environmental models representing alternative vegetation configurations, including a baseline and a modified configuration corresponding to tree removal treatments, are generated. Vegetation data in the environmental models is modified to reflect the alternative configurations. Environmental simulations are executed to compute outputs representing ecological responses. Statistical relations are generated between vegetation management actions and the simulated environmental responses, and output data is provided representing predicted outcomes, management planning information, or changes in environmental conditions.

### CLAIM OF PRIORITY

This U.S. Utility patent application claims the benefit of U.S. Provisional Patent Application No. 63/674,059, filed 22 Jul. 2024, the entire contents of which is incorporated herein by reference.

### TECHNICAL FIELD

Aspects of the disclosure relate generally to environmental modeling and simulation.

### BACKGROUND

Environmental models are used for a wide range of applications in engineering, resource management, and scientific research. These models typically represent landscapes using combinations of digital terrain data, land cover classifications, and process-based simulations to evaluate environmental dynamics. In many cases, existing models simplify or aggregate vegetation and land surface properties, which can limit their ability to account for detailed spatial variability. Current modeling approaches may not explicitly represent individual vegetation elements, making it difficult to assess the localized impacts of land cover changes on hydrologic and ecological processes.

### SUMMARY

This disclosure is directed to systems, methods, and apparatuses for integrating vegetation information into environmental models with fine spatial detail. The described techniques may include identifying individual trees and assigning tree-specific characteristics to a computational domain, such as a mesh or raster structure. These data structures may represent the spatial distribution of trees alongside terrain, channels, and watershed boundaries to support environmental simulations.

In some examples, the system enables modification of vegetation characteristics, including simulated tree removal or treatment scenarios, without requiring remeshing or topology changes. The system may also generate predictive statistical models that relate vegetation changes to environmental responses. These approaches can be used to analyze the impact of landscape modifications on hydrologic, ecological, or resource management processes. In some implementations, the statistical relationships between thinning levels and hydrologic response can be used to estimate total volumetric outputs such as increased soil water storage and streamflow expressed in acre-feet per year. These calculations consider watershed area and thinning intensity to produce actionable metrics for planning forest treatments at scale.

In at least one example, processing circuitry is configured to perform a method including: obtaining input data representing tree areas for a geographic region. In at least one example, the method includes obtaining tree characteristics for one or more tree species in the geographic region. According to certain examples, the method includes creating tree nodes based on identified tree centroids derived from the tree areas. In one example, the method includes generating spatial data structures configured to represent vegetation and terrain features based on the tree nodes and terrain data. According to such examples, the method includes applying selection criteria to partition the tree nodes into different management categories. In at least one example, the method includes generating environmental models representing alternative vegetation configurations, including a baseline vegetation configuration and a modified vegetation configuration corresponding to tree removal treatments. According to certain examples, the method includes modifying vegetation data in the environmental models to reflect changes associated with the alternative vegetation configurations. In one example, the method includes executing environmental simulations to compute outputs representing ecological responses to the alternative vegetation configurations to obtain simulated environmental responses. According to such examples, the method includes generating statistical relations between vegetation management actions and the simulated environmental responses. In at least one example, the method includes outputting data comprising one or more of: predicted outcomes, management planning information, or visualizations configured to represent changes in environmental conditions associated with the alternative vegetation configurations.

In at least one example, a system includes processing circuitry; non-transitory computer readable media; and instructions that, when executed by the processing circuitry, configure the processing circuitry to obtain input data representing tree areas for a geographic region. In one example, the system comprises instructions that, when executed, configure the processing circuitry to obtain tree characteristics for one or more tree species in the geographic region. According to such examples, the system comprises instructions that, when executed, configure the processing circuitry to create tree nodes based on identified tree centroids derived from the tree areas. In at least one example, the system comprises instructions that, when executed, configure the processing circuitry to generate spatial data structures configured to represent vegetation and terrain features based on the tree nodes and terrain data. According to certain examples, the system comprises instructions that, when executed, configure the processing circuitry to apply selection criteria to partition the tree nodes into different management categories. In one example, the system comprises instructions that, when executed, configure the processing circuitry to generate environmental models representing alternative vegetation configurations, including a baseline vegetation configuration and a modified vegetation configuration corresponding to tree removal treatments. According to such examples, the system comprises instructions that, when executed, configure the processing circuitry to modify vegetation data in the environmental models to reflect changes associated with the alternative vegetation configurations. In at least one example, the system comprises instructions that, when executed, configure the processing circuitry to execute environmental simulations to compute outputs representing ecological responses to the alternative vegetation configurations to obtain simulated environmental responses. According to certain examples, the system comprises instructions that, when executed, configure the processing circuitry to generate statistical relations between vegetation management actions and the simulated environmental responses. In one example, the system comprises instructions that, when executed, configure the processing circuitry to output data comprising one or more of: predicted outcomes, management planning information, or visualizations configured to represent changes in environmental conditions associated with the alternative vegetation configurations.

In one example, there is computer-readable storage media having instructions that, when executed, configure processing circuitry to: obtain tree characteristics for one or more tree species in the geographic region. According to certain examples, the instructions configure the processing circuitry to create tree nodes based on identified tree centroids derived from the tree areas. In one example, the instructions configure the processing circuitry to generate spatial data structures configured to represent vegetation and terrain features based on the tree nodes and terrain data. According to such examples, the instructions configure the processing circuitry to apply selection criteria to partition the tree nodes into different management categories. In at least one example, the instructions configure the processing circuitry to generate environmental models representing alternative vegetation configurations, including a baseline vegetation configuration and a modified vegetation configuration corresponding to tree removal treatments. According to certain examples, the instructions configure the processing circuitry to modify vegetation data in the environmental models to reflect changes associated with the alternative vegetation configurations. In one example, the instructions configure the processing circuitry to execute environmental simulations to compute outputs representing ecological responses to the alternative vegetation configurations to obtain simulated environmental responses. According to such examples, the instructions configure the processing circuitry to generate statistical relations between vegetation management actions and the simulated environmental responses. In at least one example, the instructions configure the processing circuitry to output data comprising one or more of: predicted outcomes, management planning information, or visualizations configured to represent changes in environmental conditions associated with the alternative vegetation configurations.

In one example, a device comprising means for obtaining input data representing tree areas for a geographic region. In at least one example, the device comprises means for obtaining tree characteristics for one or more tree species in the geographic region. According to certain examples, the device comprises means for creating tree nodes based on identified tree centroids derived from the tree areas. In one example, the device comprises means for generating spatial data structures configured to represent vegetation and terrain features based on the tree nodes and terrain data. According to such examples, the device comprises means for applying selection criteria to partition the tree nodes into different management categories. In at least one example, the device comprises means for generating environmental models representing alternative vegetation configurations, including a baseline vegetation configuration and a modified vegetation configuration corresponding to tree removal treatments. According to certain examples, the device comprises means for modifying vegetation data in the environmental models to reflect changes associated with the alternative vegetation configurations. In one example, the device comprises means for executing environmental simulations to compute outputs representing ecological responses to the alternative vegetation configurations to obtain simulated environmental responses. According to such examples, the device comprises means for generating statistical relations between vegetation management actions and the simulated environmental responses. In at least one example, the device comprises means for outputting data comprising one or more of: predicted outcomes, management planning information, or visualizations configured to represent changes in environmental conditions associated with the alternative vegetation configurations.

The details of one or more examples of the disclosure are set forth in the accompanying drawings and the description below. Other features, objects, and advantages will be apparent from the description and drawings, and from the claims.

### BRIEF DESCRIPTION OF DRAWINGS

FIG. 1 is a block diagram illustrating further details of one example of a computing device, in accordance with aspects of this disclosure.

FIG. 2 is a flowchart illustrating an example method for integrating tree data into environmental modeling workflows using multiple resolution domains, in accordance with aspects of this disclosure.

FIG. 3 illustrates watershed boundaries and monitoring infrastructure for hydrologic modeling, in accordance with aspects of this disclosure.

FIG. 4 illustrates Table 1, which summarizes watershed characteristics including vegetation composition and soil properties, in accordance with aspects of this disclosure.

FIG. 5 illustrates time series of precipitation P and streamflow discharge Q obtained from watershed regions during the study period from Jan. 1, 2016, to Dec. 31, 2019, in accordance with aspects of this disclosure.

FIG. 6 illustrates Table 2, which provides a summary of hydrologic processes and physical components that may be represented within a distributed environmental model, in accordance with aspects of this disclosure.

FIGS. 7A and 7B illustrate spatially distributed watershed parameters used for hydrologic model setup and calibration, in accordance with aspects of the disclosure.

FIG. 8 illustrates the computational domain elements developed from LiDAR-derived inputs and tree segmentation, in accordance with aspects of the disclosure.

FIG. 9 illustrates the representation of forest thinning scenarios in the hydrologic model. The figure shows pre-treatment and post-treatment conditions for a selected study area, in accordance with aspects of the disclosure.

FIG. 10 presents Table 3, which summarizes the forest treatment scenarios and corresponding polygon counts used for the hydrologic model simulations, in accordance with aspects of the disclosure.

FIG. 11 presents a comparison of simulated and observed hydrologic responses at the MS1 watershed during two calibration periods, in accordance with aspects of the disclosure.

FIG. 12 illustrates camera-based observations of streamflow conditions at a stream gauging station, in accordance with aspects of this disclosure.

FIG. 13 presents a summary of hydrologic model performance metrics, with daily resolution evaluations for four study watersheds, in accordance with aspects of this disclosure.

FIG. 14 illustrates changes in water balance components resulting from forest treatment scenarios, compared to baseline simulations, at three of the study watersheds, in accordance with aspects of this disclosure.

FIG. 15 presents Table 5, which summarizes the percent differences in annual water balance components between forest treatment scenarios, including prescribed thinning (PT), light thinning (LT), and heavy thinning (HT), and the baseline simulation for watersheds, in accordance with aspects of this disclosure.

FIGS. 16A and 16B illustrate hydrologic simulation results, in accordance with aspects of this disclosure.

FIGS. 17A and 17B illustrate the spatial distribution of total soil water storage, denoted as S in millimeters, at the start of the water year on October 1st, averaged over the study period from 2016 to 2019, in accordance with aspects of this disclosure.

FIG. 18 illustrates Table 6, summarizing the estimated hydrologic response from forest thinning treatments in the three study watersheds, in accordance with aspects of this disclosure.

FIG. 19 is a flow diagram illustrating an example method for modeling and simulating hydrologic responses to vegetation management scenarios, in accordance with aspects of this disclosure.

Like reference characters denote like elements throughout the text and figures.

### DETAILED DESCRIPTION

This disclosure is directed to systems, methods, and apparatuses for integrating vegetation information into environmental models with fine spatial detail. The described techniques may include identifying individual trees and assigning tree-specific characteristics to a computational domain, such as a mesh or raster structure. These data structures may represent the spatial distribution of trees alongside terrain, channels, and watershed boundaries to support environmental simulations.

In some examples, the system enables modification of vegetation characteristics, including simulated tree removal or treatment scenarios, without requiring remeshing or topology changes. The system may also generate predictive statistical models that relate vegetation changes to environmental responses. These approaches can be used to analyze the impact of landscape modifications on hydrologic, ecological, or resource management processes.

Computer implemented methodologies described herein may incorporate individual trees obtained at very high spatial resolution (1 meter) into a multiple resolution mesh that can be used in a range of different environmental models. To achieve this, techniques apply a set of functions that use aerial or satellite imagery or point cloud data, identify the location of each tree in a landscape, incorporate the tree location as a node of a triangulated irregular network, and build a representation of a watershed that respects the tree locations as well as other features such as channels and boundaries. Changes to tree characteristics, including removal through a natural or man-made disturbance, can be accounted for in models generated by the described methodology. In specific implementations, the hydrologic response predictions may assume no understory regrowth following tree removal. This condition provides an upper-bound estimate of treatment effects on soil water storage and streamflow for the first year after thinning. A multiple resolution mesh with the original trees or after tree removal can then serve as the domain for other software that conduct simulations of environmental processes.

Environmental models generated by the described methodology may be utilized for a range of design, engineering and management applications across multiple industry sectors. In many cases, sophisticated models represent a domain of interest, such as a project site or area, using a multiple resolution mesh that allows for capturing important details in certain regions and allowing less emphasis in other sites.

One family of multiple resolution meshes are triangulated irregular networks (TINs) used across many scientific and engineering fields (e.g., fluid mechanics, structural analysis, surface representation). The application of TINs and their associated methods for generating multiple resolution meshes is growing within environmental models that span from the entire Earth down to individual project areas.

In environmental modeling, the representation of individual sites or small locations is often important, for instance an individual pond, tree, or rock unit. These locations might have different behavior than their surroundings or experience changes over time that need to be captured in the modeling activity. However, multiple resolution meshes do not capture these individual sites or allow alterations to their properties over time. When the number of these sites is large (>1000), representing them becomes even more important within the multiple resolution mesh. Described methodologies may be configured to represent very large groups of trees in a multiple resolution mesh within a watershed area intended for modeling hydrologic and ecological processes prior to and after selective tree removal.

Other applications are also possible since the inclusion of individual sites in a multiple resolution mesh is a general problem for science and engineering modeling. The described methodology may focus on individual trees within a landscape organized into watershed areas. However, the described methodologies may also be applicable to a range of other environmental modeling domains beyond watershed hydrology. For example, urban stormwater management models may incorporate individual tree locations and characteristics to simulate rainfall interception and runoff dynamics. Ecological models may integrate tree-level data to assess habitat changes, carbon sequestration, or species distribution. Erosion models may evaluate how tree removal affeets soil stability in urban or rural environments. These examples illustrate that the described techniques are not limited to forested watershed applications but may be extended to other environmental and landscape simulations where vegetation plays a role in the modeled processes.

After deriving the tree locations from aerial or satellite imagery or point cloud data from lidar, the trees are placed inside the multiple resolution mesh and their properties arc assigned. These characteristics may include tree height, canopy cover and leaf area index, and derived quantities from these, such as radiation sheltering and interception storage. In certain implementations, tree removal scenarios may be defined using numerical thresholds for canopy height, basal area, or other metrics, in accordance with U.S. Forest Service treatment prescriptions and validated through field measurements and LiDAR data products. This allows for selective thinning operations that align with real-world forest management practices. Additional tree characteristics may include, but are not limited to, basal area, crown diameter, species identification, and stem diameter. The system may assign these characteristics to tree nodes within the mesh or to associated Voronoi polygons representing each tree. In implementations where forest treatments are simulated, such as thinning or mortality scenarios, changes to individual tree characteristics may propagate to the model by adjusting vegetation parameters in the computational domain. For example, removing a tree may reduce local leaf area index, modify interception storage capacity, alter albedo, and change transpiration rates in the corresponding mesh element or Voronoi polygon. These adjustments can be performed without modifying the mesh topology, allowing rapid scenario testing and simulation of ecological or hydrological impacts.

In addition to tree-specific parameters, the system may also incorporate non-tree land cover types such as grasslands, bare soil areas, and roads into the model parameterization. These land cover categories may be derived from aerial or satellite imagery classifications, such as those produced by the National Agriculture Imagery Program (NAIP). For each non-tree land cover type, model parameters may include albedo, canopy resistance (for vegetated surfaces), soil porosity, saturated hydraulic conductivity, and other biophysical properties relevant to the hydrologic processes. This allows the model to represent mixed landscapes, where tree removal may result in transitions to grassland or bare soil conditions, thereby modifying local water balance components.

The described methodology allows for the properties to be changed in response to a forest disturbance such as tree mortality, logging, fire, grazing, or development activities.

Forest management activities such as logging and thinning are of particular interest due to investments aimed at reducing wildfire risk in forested watersheds. In the case of forest management through thinning, a hydrologic model may be configured with two scenarios: pre-treatment and post-treatment conditions. In these scenarios, individual trees are selected to be either retained or removed from the forest based on a specified prescription. The multiple resolution mesh that captures all of the trees in the forest enables the system described herein to depict changes at the scale of individual trees for treated areas. This includes adjusting tree-related characteristics that impact biophysical processes represented in the hydrologic model.

Environmental models may be used to simulate hydrologic, ecologic and geomorphic processes, among others, in natural and urban landscapes. These models also provide a basis for assessing the impacts of changes, such as infrastructure projects, climate change and land use disturbances, on the environmental processes themselves and the ecosystem services provided by natural landscapes. The described methodologies provide a novel approach for incorporating very large numbers of individual trees into modeling domains used by environmental models. For instance, the described methodologies may utilize remote sensing data on tree locations as input to adjust a multiple resolution model domain that respects the tree locations and their properties across an entire landscape. Other landscape properties, such as the elevation distribution and the location of channels, may also be embedded into the domain.

In some examples, the hydrologic model may also include cold-season processes such as snow accumulation, snow interception by the canopy, snowmelt, and rain-on-snow events. Snowpack dynamics may be represented using coupled energy and mass balance methods, allowing the model to track snow water equivalent over time. Additional processes may include sublimation of intercepted snow from tree canopies and adjustments to infiltration rates when the soil surface is frozen. These features enable the system to simulate hydrologic responses under varying seasonal conditions, including winter-spring runoff events resulting from snowmelt or mixed precipitation.

The described methodologies may extend upon previous mesh generation approaches by providing spatial explicit information on tree locations and their characteristics, as well as the ability to represent changes in tree distributions due to disturbances, removal or mortality. Furthermore, the described methodologies are robust and can be applied to any natural landscape with trees with relative ease and higher precision as compared to traditional mesh generation methods used in environmental modeling. These methodologies may utilize the location of a large number of individual trees in a natural or urban landscape to develop a multiple resolution mesh that respects the tree locations and their properties. This capability then allows changes in trees to be readily incorporated into the environmental models built upon multiple resolution meshes. A threshold in a tree property or characteristic is applied to identify those locations that will be removed or altered within the mesh. The described methodologies may allow environmental models to be constructed for pre-treatment and post-treatment conditions with relative ease, allowing an assessment of the impacts of the disturbance on the model outputs.

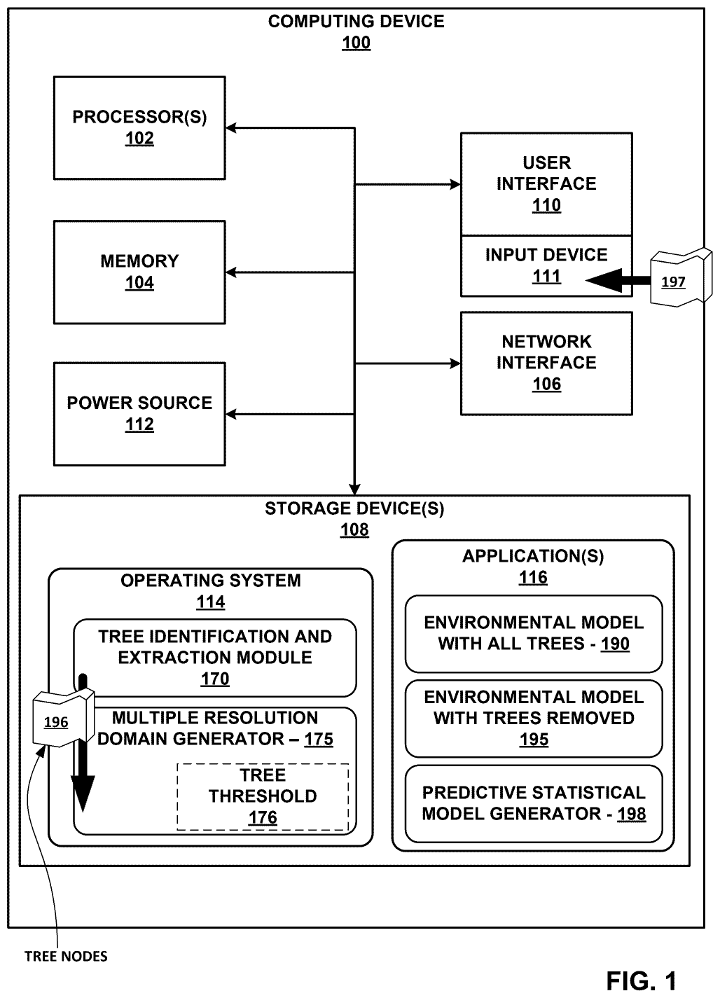

FIG. 1 is a block diagram illustrating further details of one example of computing device 100, in accordance with aspects of this disclosure. FIG. 1 illustrates only one example configuration of computing device 100. Other examples of computing device 100 may be used in various implementations.

As shown in FIG. 1, computing device 100 may include processor(s) 102, memory 104, network interface 106, storage device(s) 108, user interface 110, and power source 112. Computing device 100 may also include operating system 114. In some examples, computing device 100 further includes application(s) 116. Application(s) 116 may include environmental model with all trees 190, environmental model with trees removed 195, and predictive statistical model generator 198.

Operating system 114 may execute various functions, including tree identification and extraction module 170. Tree identification and extraction module 170 may be configured to process tree data 197 received as input. For example, tree data 197 may represent tree characteristics obtained from remote sensing sources, such as aerial imagery, satellite imagery, or point cloud data. Tree identification and extraction module 170 may generate tree nodes 196 corresponding to locations of trees within the landscape.

Tree nodes 196 may be provided to multiple resolution domain generator 175. Multiple resolution domain generator 175 may construct computational domains that represent spatial regions of interest, including but not limited to triangulated irregular network (TIN) meshes, rasterized grids, Voronoi polygons, or other domain representations. These computational domains may incorporate tree nodes 196, along with other features such as channels and watershed boundaries. In some examples, multiple resolution domain generator 175 may access tree threshold 176, which may represent a selected parameter or condition used to filter or classify trees based on characteristics such as height, canopy size, species, or basal area. Selection criteria may include applying a tree threshold, such as tree threshold 176, to tree characteristics such as height or canopy area.

Application(s) 116 may be executable by computing device 100. For example, an environmental model with all trees 190 may perform simulations using the computational domain that includes all trees, while an environmental model with trees removed 195 may perform simulations based on scenarios where selected trees are removed or modified. Predictive statistical model generator 198 may produce empirical models, such as regression-based predictive tools, that estimate environmental outcomes without requiring execution of full simulation models for each scenario.

Components of computing device 100 may be interconnected (physically, communicatively, and/or operatively) for inter-component communications. In some examples, processing circuitry, including processor(s) 102, implements functionality and/or process instructions for execution within computing device 100. For example, processor(s) 102 may be capable of processing instructions stored in memory 104 and/or instructions stored on storage device(s) 108.

Memory 104, in one example, may store information within computing device 100 during operation. Memory 104 may represent a computer-readable storage medium and, in some examples, may be volatile memory, such as RAM, DRAM, or SRAM. Memory 104 may be used to store program instructions for execution by processor(s) 102 and may temporarily store data and instructions during program execution by application(s) 116.

Storage device(s) 108, in some examples, may also include computer-readable storage media for long-term storage of information. Examples include magnetic hard disks, optical discs, flash memory, or forms of electrically programmable memories (EPROM, EEPROM).

Computing device 100 may include network interface 106, which may enable communication with external devices over wired or wireless networks. Network interface 106 may include Ethernet, optical transceivers, radio frequency transceivers, cellular radios, BLUETOOTH®, Wi-Fi®, LTE, USB, or other communication hardware.

User interface 110 may include input device 111, such as a touch-sensitive display, mouse, keyboard, microphone, camera, or voice responsive system. User interface 110 may also include output devices, such as a display screen, speakers, or other devices that provide output to a user via visual, auditory, or tactile feedback.

Power source 112 may provide electrical power to computing device 100. Power source 112 may include a rechargeable battery, such as lithium-ion, nickel-cadmium, or other suitable battery technologies.

Operating system 114 may be stored in storage device(s) 108 and may control the operation of hardware components within computing device 100. Operating system 114 may facilitate execution of application(s) 116, including modules and models described herein.

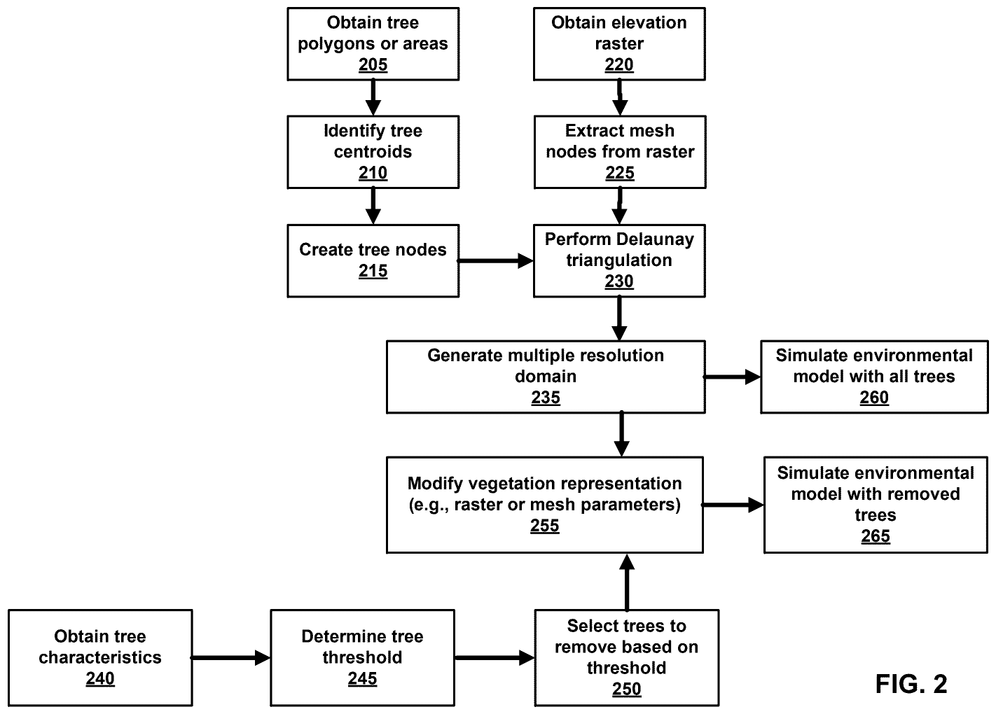

FIG. 2 is a flowchart illustrating an example method for integrating tree data into environmental modeling workflows using multiple resolution domains, in accordance with aspects of this disclosure. FIG. 2 provides one example of the logical flow; variations in sequence or implementation may be possible.

Obtain tree polygons or areas 205 represents acquiring tree canopy delineations from remote sensing data. For example, aerial or satellite imagery or a three-dimensional point cloud from lidar may be processed to identify tree areas within a landscape and distinguish them from non-tree regions. The output may include geospatial data layers, such as shapefiles, containing tree canopy boundaries.

Identify tree centroids 210 includes calculating the centroid of each tree polygon using operations in a geographic information system (GIS). The result may be a set of geospatial points representing the central locations of the tree canopies, stored in a shapefile or equivalent format.

Create tree nodes 215 includes converting each centroid to a three-dimensional X, Y, Z point and assigning each node a boundary flag, such as a flag of zero to signify an interior node. This step may be performed in GIS software, resulting in a table of tree node coordinates and corresponding flags.

Obtain elevation raster 220 includes acquiring a digital elevation model (DEM) representing ground surface elevations. The DEM may be obtained from lidar data or other elevation products at various spatial resolutions. Hydrologic processing of the DEM may generate watershed boundaries and internal channel networks, outputting geospatial layers that describe watershed characteristics.

Extract mesh nodes from raster 225 includes selecting specific nodes from the processed elevation raster that are required for domain generation, such as boundary points, channel points, and interior points. Each node may be assigned a boundary flag and stored in a table of coordinates.

Perform Delaunay triangulation 230 combines tree nodes from create tree nodes 215 with watershed nodes from extract mesh nodes from raster 225 to generate connectivity relationships between points. This may be implemented using constrained Delaunay triangulation or similar methods.

Generate multiple resolution domain 235 represents the construction of a computational domain using the triangulated points, resulting in a mesh, raster, or hybrid representation that captures both terrain and vegetation features at different resolutions. The output may include geospatial data layers describing the domain topology.

Obtain tree characteristics 240 includes extracting relevant tree metrics from remote sensing data. For example, tree height, canopy area, basal area, or species classification may be obtained from lidar data, aerial imagery, or field surveys.

Determine tree threshold 245 involves applying a threshold to the obtained tree characteristics to differentiate between trees that meet criteria for removal and those that do not. For example, a height threshold may be used to classify trees as eligible or ineligible for treatment. Other metrics may also be used as thresholds, depending on management objectives.

Select trees to remove based on threshold 250 includes applying the determined threshold to identify specific trees for removal in the scenario analysis. This selection may be based on forest management prescriptions, disturbance scenarios, or other ecological considerations.

Modify vegetation representation 255 involves adjusting vegetation properties in the computational domain for the trees selected for removal. For example, raster data or mesh parameters may be updated to reflect the absence of specific trees or changes to canopy structure. The result is a modified vegetation representation suitable for input to environmental models.

Simulate environmental model with all trees 260 refers to executing the environmental model using the original multiple resolution domain without modifications, representing pre-treatment or baseline conditions.

Simulate environmental model with removed trees 265 refers to executing the environmental model using the modified vegetation representation, reflecting tree removal or treatment scenarios. Comparisons may be made between a simulated environmental model with all trees 260 and a simulate environmental model with removed trees 265 to assess the impact of vegetation changes on hydrologic or ecological processes.

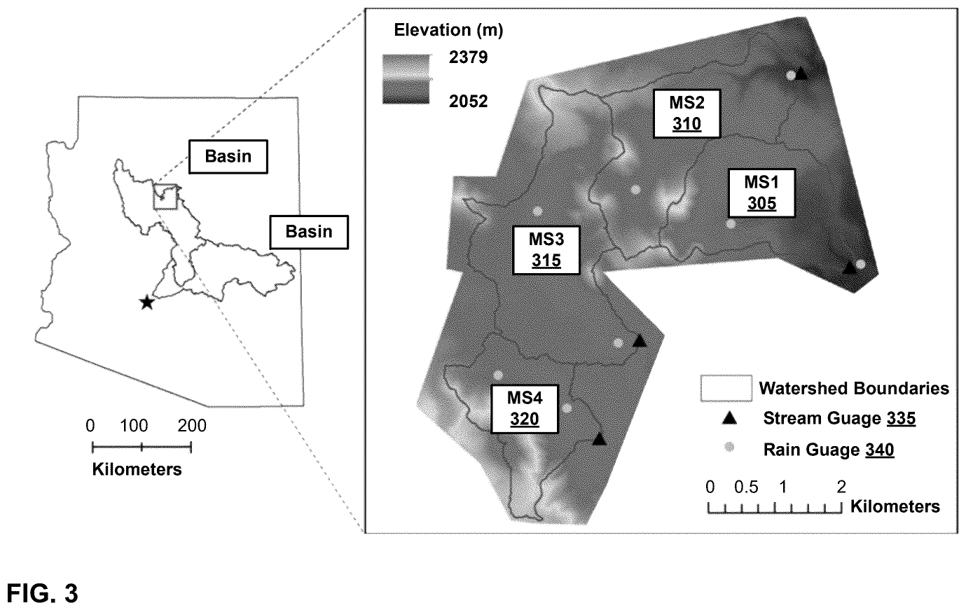

FIG. 3 illustrates watershed boundaries and monitoring infrastructure for hydrologic modeling, in accordance with aspects of this disclosure. FIG. 3 includes watershed regions MS1 305, MS2 310, MS3 315, and MS4 320, which are delineated from a high-resolution digital elevation model (DEM) derived from helicopter-mounted lidar measurements. In areas with data gaps, the DEM was supplemented using USGS 1-meter elevation products.

Watershed regions MS1 305, MS2 310, MS3 315, and MS4 320 have independent outlets and similar drainage areas, with MS3 315 representing the largest watershed. The total combined area of the watersheds is approximately 18 km² (4436 acres). Elevation within the watersheds ranges from 2379 meters in the southwest of MS4 320 to 2052 meters at the outlet of MS1 305.

Each watershed region includes hydrologic monitoring infrastructure. Stream gauge 335 is installed at the outlet of each watershed region to measure streamflow. Rain gauge 340 pairs are positioned within each watershed to capture spatially distributed precipitation data. The locations of stream gauge 335 and rain gauge 340 are shown in FIG. 3.

The small inset map in FIG. 3 displays the location of the study watersheds within the regional basin context, providing geographic orientation within the state of Arizona. The inset highlights the location of basin 300, indicating the relative position of the monitored watersheds.

Watershed boundaries are delineated based on hydrologic processing of the DEM, as shown by the solid line partitions in FIG. 3. Each watershed boundary reflects the terrain-driven flow paths derived from lidar measurements, ensuring accurate partitioning of surface runoff.

Watershed region MS1 305 serves as a control site without forest treatment scenarios. Watershed regions MS2 310, MS3 315, and MS4 320 represent treatment areas where forest thinning and vegetation management scenarios are simulated. These areas are selected to assess the impact of vegetation removal on hydrologic conditions, including changes in evapotranspiration, soil water storage, and streamflow generation.

In some examples, hydrologic models described herein may be initialized and calibrated using observational data from stream gauge 335 and rain gauge 340 within watershed regions MS1 305, MS2 310, MS3 315, and MS4 320. This configuration enables simulation of baseline (pre-treatment) and scenario (post-treatment) conditions across multiple small-scale basins.

The geographic region modeled includes Level III ecoregion vegetation primarily composed of ponderosa pine (Pinus ponderosa), with patches of quaking aspen (Populus tremuloides), Gambel oak (Quercus gambelii), and valley bottom grasses such as Bouteloua gracilis and Festuca arizonica. Soils in watershed regions MS1 305 to MS4 320 are classified as alfisols, with subsurface clay accumulation. Surface soils are characterized as loamy and clay-loamy in texture, with higher clay fractions in MS4 320 as indicated by the ISRIC SoilGrids250m dataset.

In some examples, the system may generate statistical models or predictive relations that link vegetation management actions to changes in hydrologic outcomes, using data from watershed regions MS1 305, MS2 310, MS3 315, and MS4 320. These models can provide rapid assessments of hydrologic impacts associated with different levels of tree removal, without requiring rerunning the full simulation for each scenario.

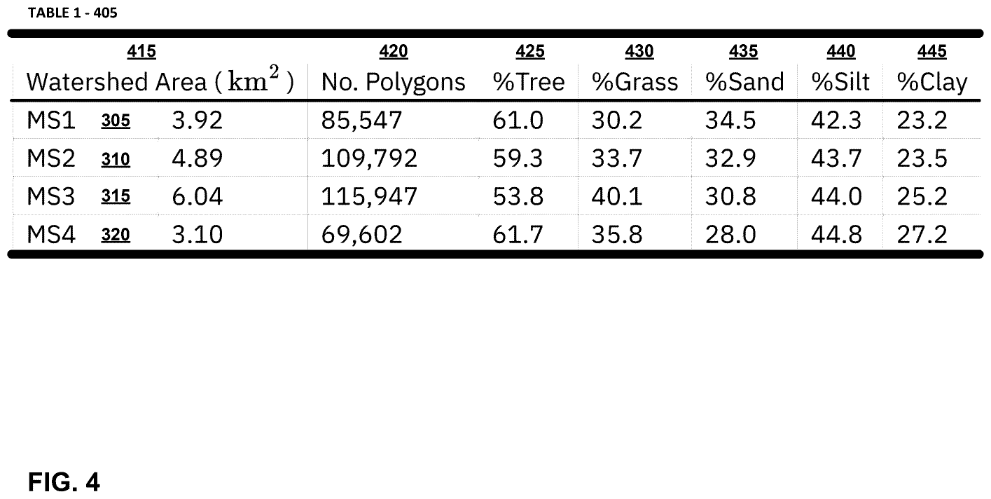

FIG. 4 illustrates Table 1 at element 405, which summarizes watershed characteristics including vegetation composition and soil properties, in accordance with aspects of this disclosure. Table 1-405 includes watershed area 415 in square kilometers, number of polygons 420 representing the computational domain, percentage of tree cover 425, percentage of grass cover 430, and average soil particle size distribution, including percentage of sand 435, percentage of silt 440, and percentage of clay 445.

The data in Table 1-405 are used to initialize vegetation and soil parameters in the hydrologic model. For example, percentage of tree cover 425 and percentage of grass cover 430 may be inputs to evapotranspiration and canopy interception functions. Soil texture values, including percentage of sand 435, percentage of silt 440, and percentage of clay 445, may be used in equations to determine field capacity, wilting point, and infiltration rates. In some examples, the system applies empirical relations, such as the Rawls-Brakensick or Saxton formulas, to compute soil hydraulic properties from these texture data.

Watershed regions MS1 305, MS2 310, MS3 315, and MS4 320 are discretized using a number of polygons 420, which define mesh or raster elements for simulations.

Hydrological and meteorological observations were collected during a study period from Jan. 1, 2016, to Dec. 31, 2019. Each watershed region was instrumented with stream gauge 335 and rain gauge 340 (see FIG. 3). Precipitation, denoted as P, was measured in millimeters per 15-minute interval using baffled weighing gauges capable of capturing both liquid and solid forms of precipitation. Streamflow discharge, denoted as Q, was measured in cubic meters per second (m³/s) at 15-minute intervals using pressure transducers at the outlet of each watershed region, converted to Q values through site-specific rating curves. Visual data from SRP Flowtography® systems were used to validate streamflow observations.

These observed P and Q time series were used to calibrate and validate the hydrologic model simulations, ensuring accurate representation of pre-treatment watershed behavior.

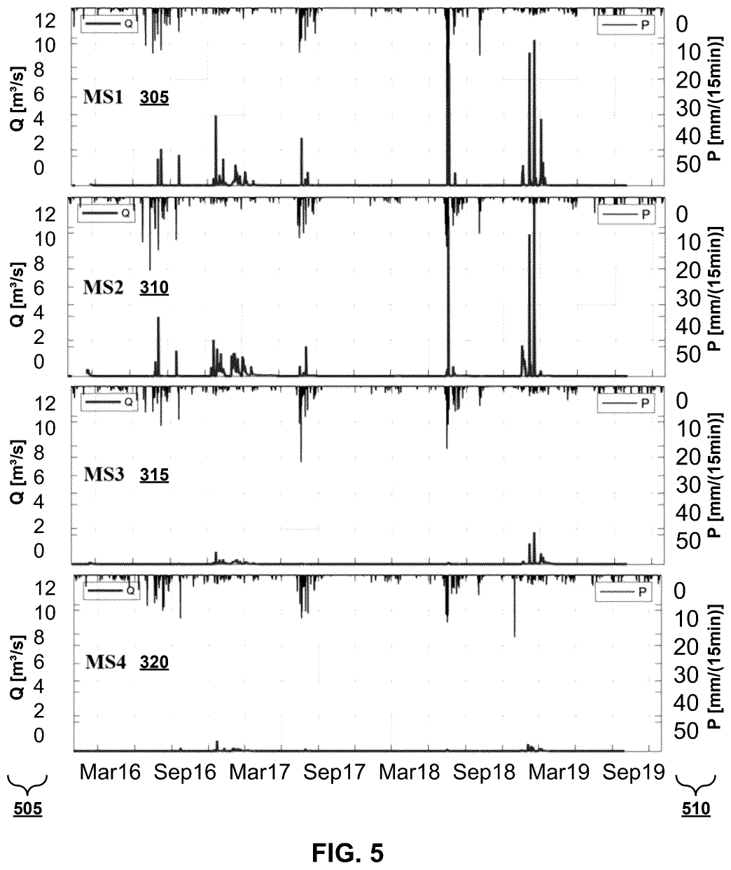

FIG. 5 illustrates a time series of precipitation P 505 and streamflow discharge Q 510 obtained from watershed regions MS1 305, MS2 310, MS3 315, and MS4 320 during the study period from Jan. 1, 2016, to Dec. 31, 2019, in accordance with aspects of this disclosure. Precipitation P 505 is measured in millimeters per 15-minute interval [mm/15 min], and streamflow discharge Q 510 is measured in cubic meters per second [m³/s].

The time series of P 505 and Q 510 provide indications of the hydrologic responses to meteorological forcing within each watershed region. Notably, larger discharge responses are observed in watershed regions MS1 305 and MS2 310 compared to MS3 315 and MS4 320.

Seasonal patterns are evident in the time series. More intense precipitation events occur during the North American monsoon period (July to September), while winter-spring events (October to April) tend to be less intense and occur over longer durations. Precipitation data from the two rain gauges 340 installed in each watershed region were processed using Thiessen polygon weighting to compute spatially averaged precipitation inputs for the hydrologic model.

Additional meteorological data required by the model include air temperature, relative humidity, wind speed, atmospheric pressure, and incoming solar radiation. These inputs were obtained from a combination of eight Meso West meteorological stations and data products from the North American Land Data Assimilation System (NLDAS). These meteorological forcing data were used alongside P 505 and Q 510 records for model calibration, validation, and scenario analysis.

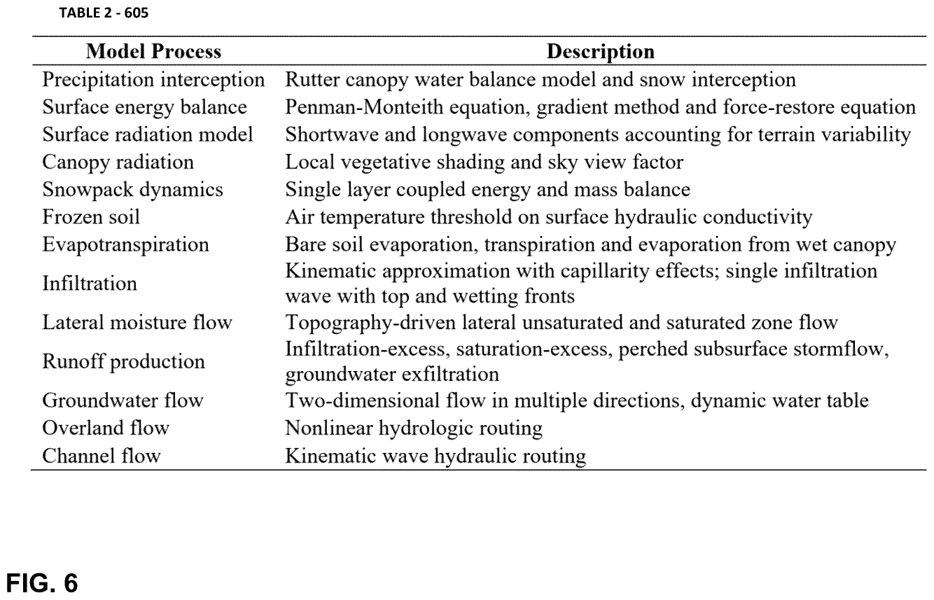

FIG. 6 illustrates Table 2-605, which provides a summary of hydrologic processes and physical components that may be represented within a distributed environmental model, in accordance with aspects of this disclosure.

In some examples, the system may employ a triangular irregular network (TIN) mesh and associated Voronoi polygons to simulate hydrologic processes across a watershed. One example implementation includes the TIN-based Real-time Integrated Basin Simulator (tRIBS), which features a distributed-parameter, continuous, coupled surface and subsurface modeling framework. Originally developed with formulations for infiltration, runoff, and evapotranspiration, subsequent extensions have expanded the model to represent additional processes such as cold season dynamics, snow accumulation and melt, reservoirs, and channel transmission losses.

Table 2-605 lists examples of hydrologic and environmental processes that may be modeled. These processes include precipitation interception, energy and radiation balance, canopy radiation effects, snowpack dynamics, frozen soil interactions, evapotranspiration, infiltration, lateral moisture movement, runoff generation, groundwater flow, overland flow, and channel flow. Each process may be represented using one or more formulations, such as the Penman-Monteith equation for evapotranspiration or kinematic wave routing for channel flow. The model may allow for parameterization adjustments or user-defined selections to account for varying watershed conditions.

In some implementations, the system may include reservoir routing functions using a level-pool method, in which reservoir outflow is determined by storage volume and predefined stage-storage-discharge relationships. This approach enables simulation of managed flow releases for purposes such as flood control, water supply, or ecological management.

Additionally, the system may represent channel transmission losses by assigning infiltration or loss coefficients to stream segments. These coefficients may reflect local conditions such as channel permeability or groundwater gradients, allowing simulation of losing stream reaches where surface flow infiltrates into the subsurface during transport. This capability is particularly relevant in semi-arid and arid regions.

The described processes were applied to the four study watersheds for this analysis. The methodology builds on prior applications in ponderosa pine regions of New Mexico and Arizona, with increased spatial resolution and incorporation of real-world forest thinning scenarios.

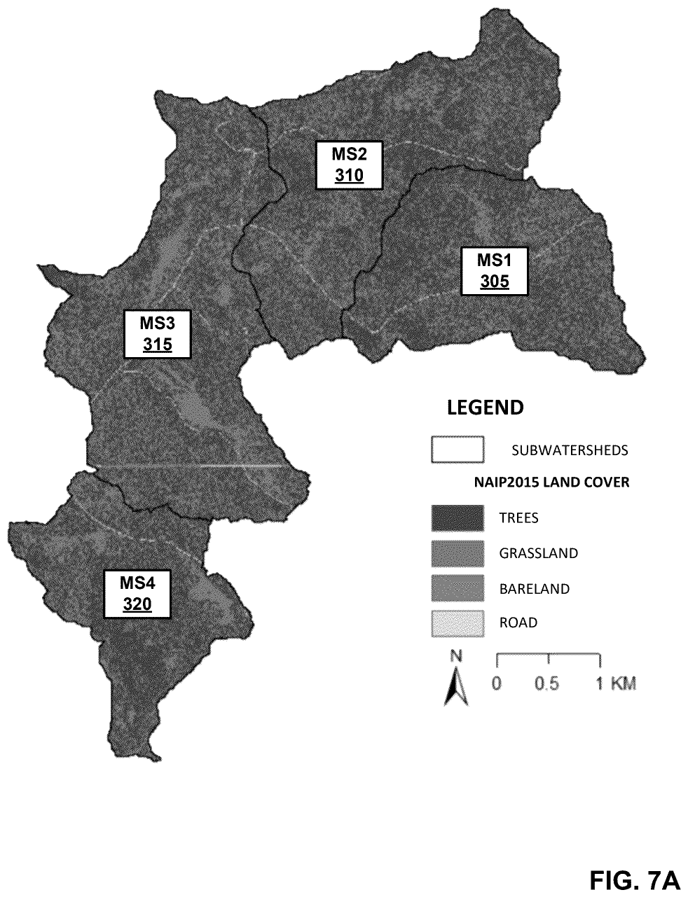

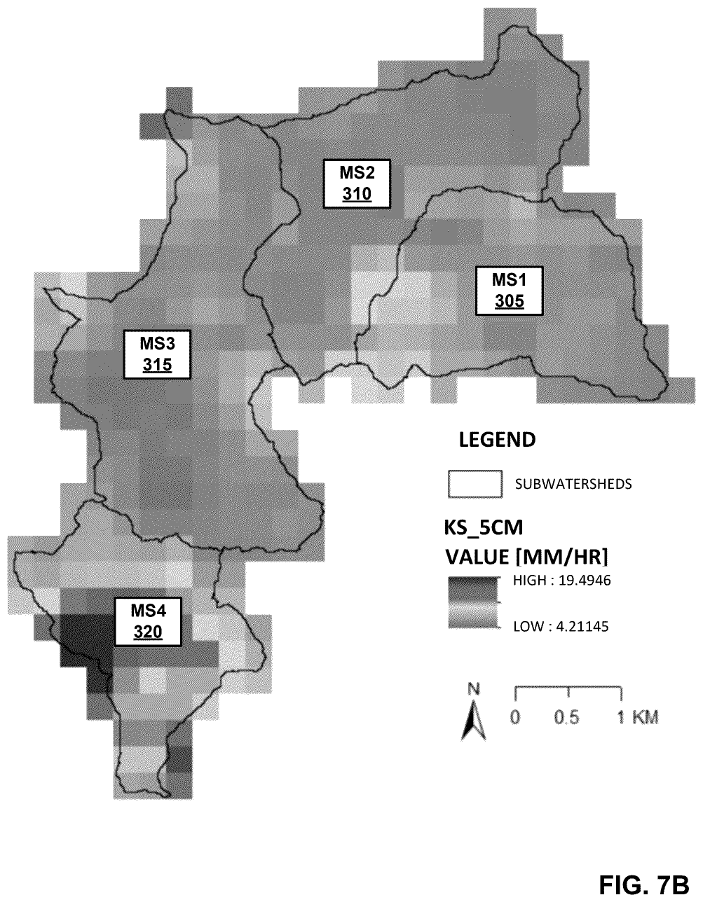

FIGS. 7A and 7B illustrate spatially distributed watershed parameters used for hydrologic model setup and calibration, in accordance with aspects of the disclosure.

FIG. 7A provides land cover classification obtained from a 2015 National Agriculture Imagery Program (NAIP) 1 m resolution image. Land cover classes include trees, grassland, bareland, and roads, and are delineated at the watershed level for MS1 305, MS2 310, MS3 315, and MS4 320. Subwatershed boundaries are overlaid to define model domains.

FIG. 7B shows saturated hydraulic conductivity at the top 5 cm of soil (Ks), derived from the International Soil Reference and Information Centre (ISRIC) dataset at 250 m resolution. The Ks values range from 4.21145 mm/hr to 19.4946 mm/hr, spatially mapped for each subwatershed.

Hydrologic Model Parameterization, Calibration, and Initialization: The tRIBS model was applied to the four watersheds using high-resolution Light Detection and Ranging (LiDAR) data products, including 1 m bare-earth DEMs, tree segmentation, canopy heights, and leaf area index fields. Land use classifications from FIG. 7A were integrated into the computational domain, alongside soil texture information from FIG. 7B.

To incorporate individual tree segments into the Voronoi polygon network of the model domain, the number of Voronoi polygons was significantly increased, as shown in Table 1 (FIG. 4). This increase required parallel computing approaches and execution on Arizona State University's Agave cluster, using up to eight computing nodes per run.

In some implementations, containerization tools (e.g., Docker) or build systems (e.g., CMakc) may be employed for reproducible software deployment. Graph partitioning algorithms, such as METIS, may facilitate domain subdivision for distributed computing. Parallel processing strategies may include mesh partitioning, distributed tree characteristic storage, and task scheduling for scenario simulations.

Model initialization used a spin-up period repeating three years of meteorological data to stabilize soil moisture, groundwater, and snowpack conditions. Calibration was performed initially on MS1 305 at coarse resolution (3850 Voronoi polygons), then extended to high-resolution simulations for all watersheds (see Table 1, FIG. 4). Full simulation runs, including spin-up and the 2016-2019 study period, required approximately 120 hours on the Agave cluster.

Calibration parameters were adjusted to match observed winter-spring and summer streamflow (see FIG. 5), gridded snow water equivalent (SWE) datasets, and overall water balance partitioning. Adjustments included modifying: (1) the air temperature threshold for rain-snow partitioning, (2) the snow interception coefficient linked to leaf area index, and (3) saturated hydraulic conductivity Kₛ, setting Kₛ=0.1 mm/hr under frozen conditions.

Visual observation data, including SRP Flowtography® imagery, were used to verify model output, event timing, and hydrologic transitions, providing complementary validation alongside sensor data.

Hydrologic Model Representation of Forest Structure and Treatment Scenarios: The described methodology integrates tree segments directly into the Voronoi polygon framework of a TIN-based hydrologic model. This approach enables detailed vegetation representation and allows for scenario-based forest thinning operations without altering the mesh geometry.

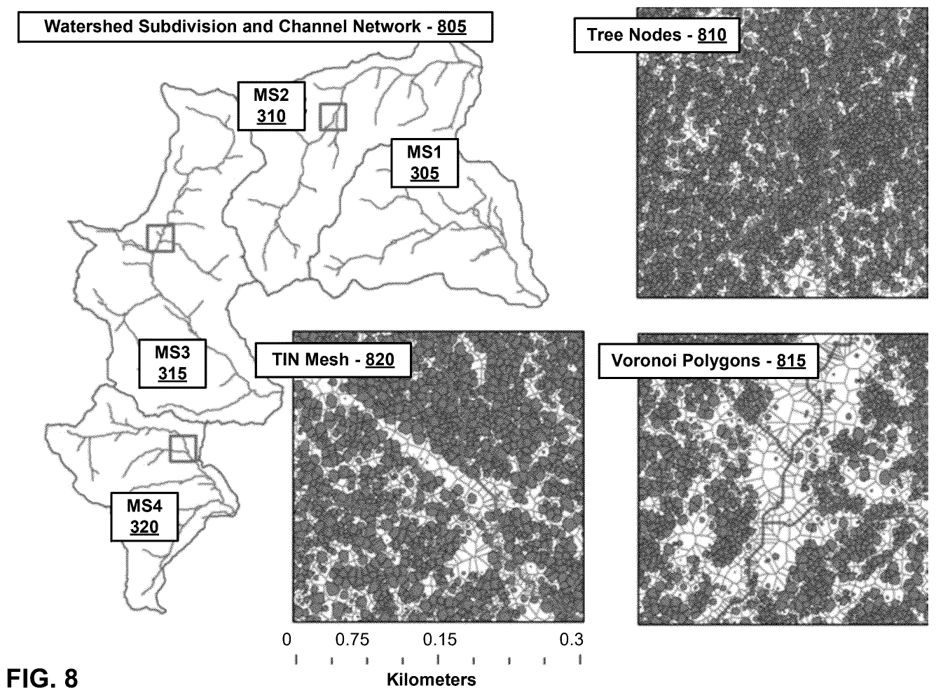

FIG. 8 illustrates the computational domain elements developed from LiDAR-derived inputs and tree segmentation, in accordance with aspects of the disclosure. Watershed Subdivision and Channel Network 805 depicts the delincation of MS1 305, MS2 310, MS3 315, and MS4 320 along with their channel networks. These boundaries and channels are derived from high-resolution digital elevation data processed through hydrologic analysis methods.

Tree Nodes 810 represent the centroids of individual trees identified from LiDAR segmentation algorithms. These nodes are assigned specific vegetation attributes such as height, canopy diameter, and basal area, providing localized vegetation characteristics for the model.

Voronoi Polygons 815 illustrate the partitioning of the domain into computational elements. In forested areas, each Voronoi polygon typically contains a single tree, allowing model parameters to align with individual tree processes such as root water uptake, canopy interception, snow sublimation, and shading effects. In contrast, polygons are larger in grasslands or open areas, reflecting homogenous surface conditions where fewer vegetation interactions occur.

TIN Mesh 820 shows the constrained Delaunay triangulation combining watershed structure and tree nodes. This mesh defines the surface flow network, supporting dynamic routing while retaining tree-level vegetation resolution.

The use of tree-specific Voronoi polygons significantly increases the number of computational elements relative to coarser terrain-only models (see Table 1, FIG. 4). However, parallel processing techniques maintain computational feasibility. By embedding tree segments directly into the hydrologic domain, this method provides two advantages: (1) vegetation parameters are resolved at a scale consistent with individual tree processes, and (2) trees can be selectively removed to simulate thinning or disturbance scenarios without requiring remeshing or altering the underlying domain structure. Furthermore, the statistical relations derived from model simulations may be applied across multiple watersheds to generate generalized estimates of hydrologic change at varying thinning levels. This enables rapid assessment of different forest management strategies across different landscape units without the need to rerun full hydrologic simulations for each case.

This configuration supports efficient representation of both natural and managed forest conditions, facilitating scenario analyses related to forest treatment planning and hydrologic response evaluation.

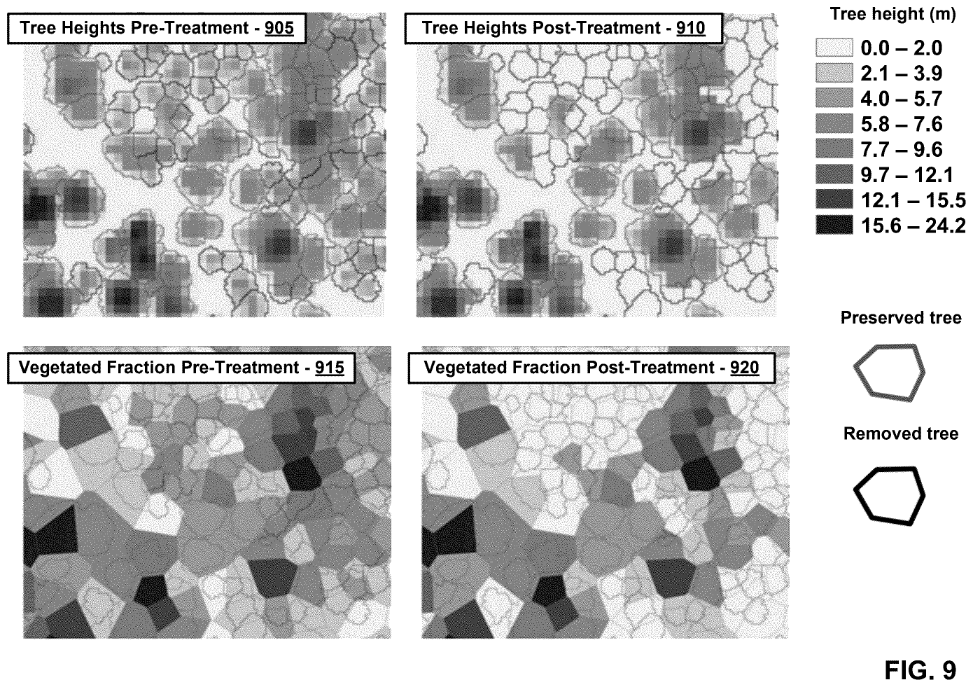

FIG. 9 illustrates the representation of forest thinning scenarios in the hydrologic model. The figure shows pre-treatment and post-treatment conditions for a selected study area, in accordance with aspects of the disclosure.

At element 905, a pre-treatment tree height map is depicted. Tree heights are shown using a grayscale color ramp, where lighter shades correspond to shorter trees and darker shades correspond to taller trees, as indicated by the tree height legend (0.0-24.2 meters). Each tree segment is associated with a Voronoi polygon, consistent with the computational domain used in the hydrologic model. Preserved trees are outlined in gray, and trees designated for removal are outlined in black.

At element 910, a post-treatment tree height map is shown. In this illustration, tree removal has been applied by thinning the shorter and smaller-diameter trees while retaining larger, taller trees. The resulting map reflects the updated vegetation structure, with removed trees no longer contributing to canopy processes.

At element 915, the pre-treatment vegetated fraction is depicted for each Voronoi polygon. The vegetated fraction refers to the proportion of the polygon area covered by tree canopy, based on the segmented tree footprints derived from LiDAR. Darker shades indicate polygons with a larger vegetated fraction, while lighter shades represent polygons with less canopy cover.

At element 920, the post-treatment vegetated fraction is illustrated. Following tree removal, the vegetated fraction in each polygon is updated to reflect changes in canopy cover. Removed trees are excluded from the vegetated fraction computation, allowing the model to capture the spatial redistribution of vegetation properties after thinning.

In some examples, the described method enables tree removal operations to be performed directly within the Voronoi polygon network without altering the underlying mesh geometry. Tree canopy parameters, such as interception, transpiration, and shading, are recalculated for each polygon based on the remaining trees. This approach facilitates the simulation of forest management scenarios, where various thinning prescriptions can be implemented by modifying tree attributes while retaining the computational structure of the hydrologic model.

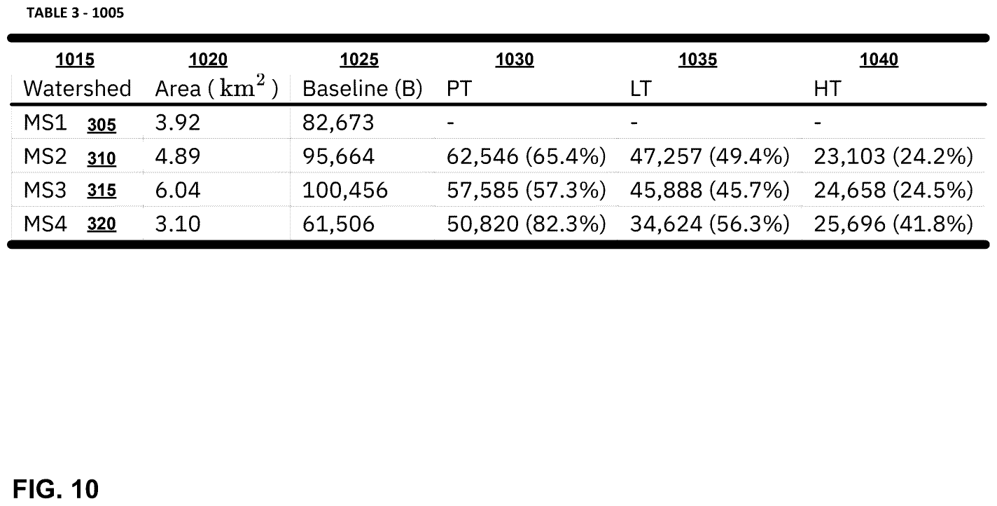

FIG. 10 presents Table 3 at element 1005, which summarizes the forest treatment scenarios and corresponding polygon counts used for the hydrologic model simulations, in accordance with aspects of the disclosure. Tree centroids 1015 may be identified and represented as points within a geographic region. Tree nodes 1020 may be generated from the tree centroids 1015. Selected tree 1025 represents a tree identified for a management action, such as removal. Removed tree 1030 represents a tree flagged for deletion or modification in a vegetation management operation. Remaining tree 1035 represents a tree retained in the baseline vegetation configuration. Tree location data 1040 includes labels or markers indicating the positions of trees in the spatial dataset. The table includes the total number of Voronoi polygons representing trees and terrain features under baseline conditions, along with three treatment scenarios: prescribed thinning (PT), light thinning (LT), and heavy thinning (HT). Each treatment reduces the number of trees to different extents based on management guidelines while retaining computational elements for non-vegetated areas.

The PT scenario represents a management-based thinning where trees were selectively removed or retained in specific treatment polygons to meet basal area targets defined by real-world forest operations. This approach preserves certain trees for ecological and habitat considerations, such as maintaining minor tree species (e.g., Gambel oak, yellow pinc), providing habitat structures for bird species, and promoting savanna-like or grassland conditions where appropriate. In PT cases, thinning treatments were implemented to reflect realistic forest management prescriptions.

The LT and HT scenarios reflect uniform thinning across the watershed, where trees were removed based on canopy height, diameter at breast height, crown-to-height ratios, and species characteristics. These scenarios systematically reduce tree density to specified percentages in each watershed, simulating increasingly intensive thinning conditions.

Table 3 (FIG. 10) reports the number of Voronoi polygons associated with trees for each treatment scenario and the baseline case. For MS1, no thinning treatments were applied, maintaining it as a control watershed for comparison purposes in both model simulations and potential field operations. The percentages shown in parentheses indicate the proportion of trees retained in each watershed for the respective treatment scenarios. These values were used to quantify the hydrologic response across a suite of simulations, including baseline and treatment cases for MS2, MS3, and MS4, resulting in a total of 13 scenarios modeled.

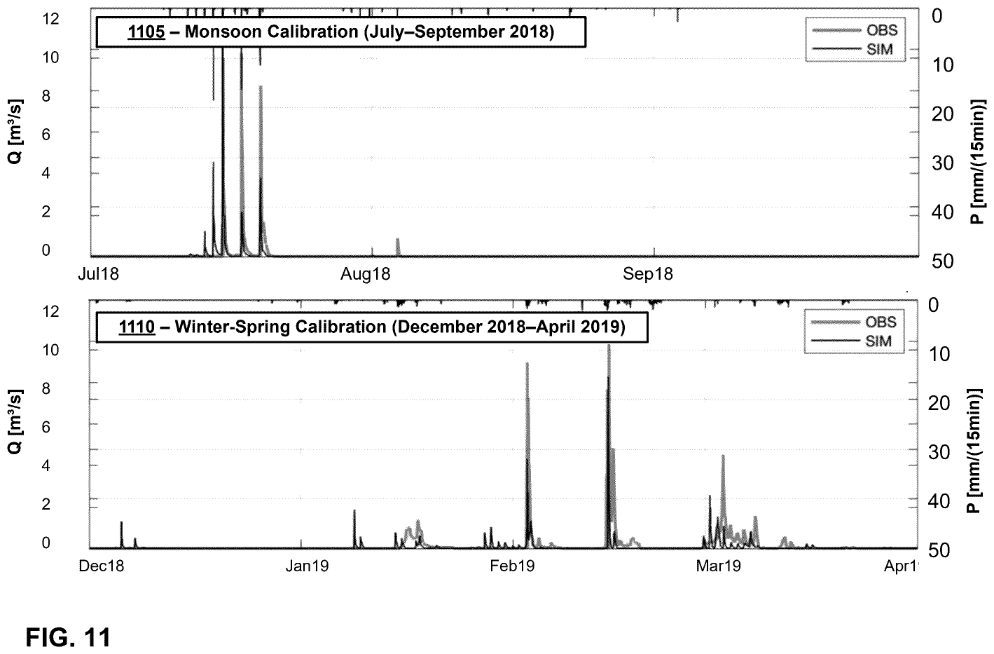

FIG. 11 presents a comparison of simulated and observed hydrologic responses at the MS1 watershed during two calibration periods, in accordance with aspects of the disclosure. Panel 1105 illustrates the summer monsoon calibration period, covering July through September 2018. Panel 1110 illustrates the winter-spring calibration period, covering December 2018 through April 2019. In both cases, streamflow discharge (Q) is shown in cubic meters per second (m³/s) on the left axis, with observed (OBS) and simulated (SIM) time series plotted at hourly resolution. Precipitation (P) is displayed on the inverted right axis in millimeters per 15-minute interval, providing context for rainfall-driven runoff events. These comparisons were used to evaluate model fidelity in representing both monsoonal and winter-spring hydrological dynamics, including the timing and magnitude of streamflow responses to precipitation inputs.

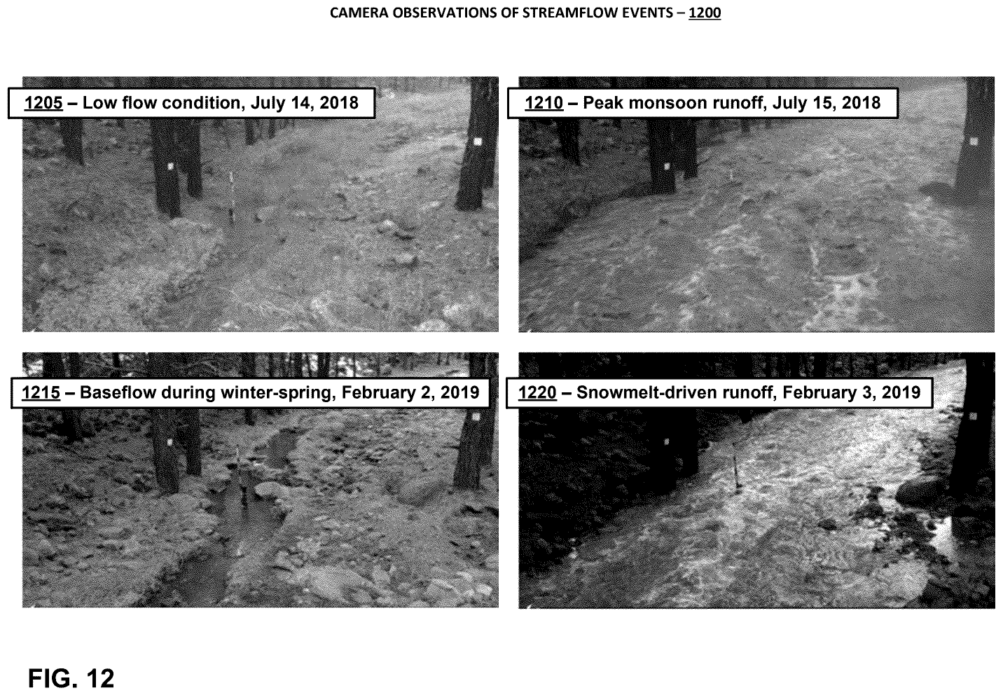

FIG. 12 illustrates camera-based observations of streamflow conditions at the MS1 stream gauging station, corresponding to element 1200, in accordance with aspects of this disclosure. Reference numeral 1205 illustrates a low flow condition on Jul. 14, 2018, representing a typical dry channel state prior to monsoon precipitation. Reference numeral 1210 shows peak monsoon runoff captured on Jul. 15, 2018, resulting from high-intensity precipitation in liquid form. Reference numeral 1215 displays baseflow conditions during the winter-spring period on Feb. 2, 2019, characterized by minimal channel flow primarily driven by subsurface contributions. Reference numeral 1220 depicts a snowmelt-driven runoff event on Feb. 3, 2019, resulting from low-intensity liquid precipitation falling on a partially thawed snowpack, leading to combined surface and subsurface flow contributions. These photographic observations were used to support hydrologic model calibration by providing visual evidence of flow conditions in correspondence with simulation results.

Hydrologic model calibration and evaluation procedures were conducted to increase confidence in the streamflow simulations generated under baseline watershed conditions. Visual observations from the camera system shown in FIG. 12 were compared to modeled streamflow outputs to verify the representation of runoff processes. For example, daily images confirmed that the model accurately reproduced rapid runoff responses to summer monsoon events, consistent with infiltration-excess runoff mechanisms. During winter-spring conditions, model simulations captured snowmelt-driven flow and baseflow contributions consistent with the observed stream conditions. The photographic records supplemented quantitative streamflow data and provided independent confirmation of hydrologic transitions between event and non-event periods. These comparisons helped validate the model representation of both summer and winter hydrologic processes, including infiltration-excess runoff, subsurface storage contributions, and evapotranspiration dynamics from trees, grasses, and bare soil areas.

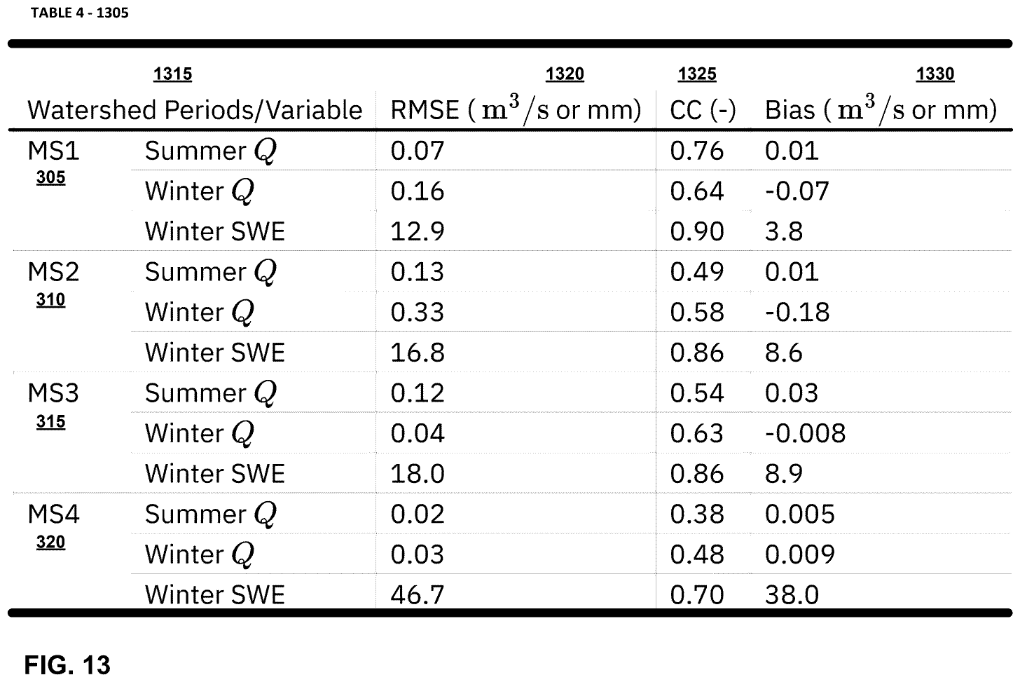

FIG. 13 presents a summary of hydrologic model performance metrics at element 1305, with daily resolution evaluations for four study watersheds MS1 305, MS2 310, MS3 315, and MS4 320, in accordance with aspects of this disclosure. Multi-resolution TIN mesh 1315 represents a data structure configured to model terrain and vegetation features at varying levels of detail. The multi-resolution TIN mesh 1315 includes elements that can represent tree nodes, canopy height, and terrain elevation data in an integrated geospatial dataset. Table 4 summarizes model results for outlet streamflow (Q) and basin-averaged snow water equivalent (SWE) across two seasonal periods: summer (July to September) and winter-spring (December to March). Three performance metrics are reported, including root mean squared error (RMSE) at reference numeral 1320, correlation coefficient (CC) at reference numeral 1325, and bias at reference numeral 1330. Observed Q values were obtained from Salt River Project (SRP) gauging stations, while SWE observations were derived from gridded datasets at approximately 4 km resolution.

The results indicate favorable model performance for summer Q across the four watersheds, with low RMSE and bias values and acceptable CC levels for daily streamflow simulations. During winter-spring periods, hydrologic processes were more varied and included contributions from snowmelt, rainfall, and rain-on-snow events. This complexity was verified through SRP Flowtography® observations that captured transitions between flow regimes. For example, FIG. 12 blocks 1215 and 1220 illustrate conditions before and during a snowmelt-driven runoff event that followed a rainfall input on a sparse snowpack. The model successfully reproduced these dynamics, as shown in the streamflow results for winter periods (see 305-320 in FIG. 13) and in the simulated SWE values that align with the coarse-resolution observational product.

The table indicates that for most watersheds, both summer and winter-spring streamflow were captured with similar levels of accuracy. However, in MS4 320, higher RMSE and bias values were noted for winter SWE. This result may reflect challenges in representing snow accumulation and melt in smaller basins or regions with higher variability in snow cover. Despite this, the model retained the ability to reproduce key hydrologic responses, including gradual baseflow increases and event-driven peak flows during winter and spring. The approach included simulating snow accumulation, meltwater generation, and partitioning between runoff and soil water storage, allowing the system to capture hydrologic responses over both short and extended timescales.

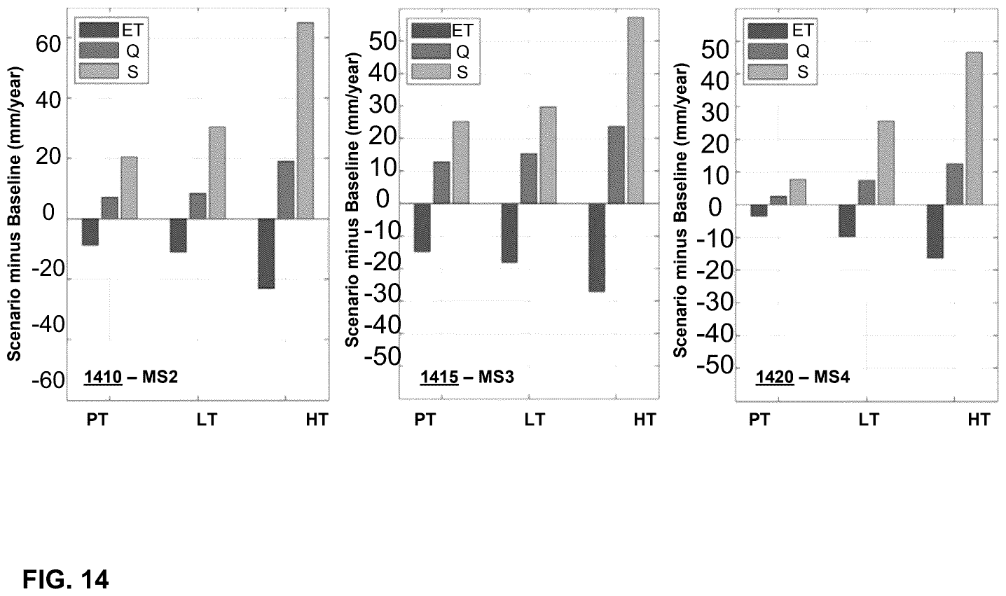

FIG. 14 illustrates changes in water balance components resulting from forest treatment scenarios, compared to baseline simulations, at three of the study watersheds, including MS2 1410, MS3 1415, and MS4 1420, in accordance with aspects of this disclosure. Multi-scale management area 1410 corresponds to a spatial dataset integrating vegetation management across different scales. Tree-level management region 1415 represents fine-grained data for individual trees or tree clusters. Watershed-scale management region 1420 defines broader zones used for ecological simulation and hydrologic modeling. Watershed-scale management region 1420 represents a broader area encompassing multiple tree-level regions, supporting hydrologic and ecological simulations at the watershed level. The water balance components include evapotranspiration (ET), streamflow (Q), and soil water storage(S), all expressed in millimeters per year. The values represent the difference between each forest management scenario and the baseline case, computed as scenario minus baseline. Each bar reflects an average over multiple water years, from October 1 to September 30, covering the full study period. Three treatment scenarios were considered: PT (prescribed thinning), LT (light thinning), and HT (heavy thinning). The diagrams show that as thinning intensity increases from PT to HT, ET generally decreases, while Q and S tend to increase, though the specific magnitudes vary by watershed and treatment level. These results highlight the potential hydrologic consequences of vegetation management, with heavier thinning leading to larger shifts in water partitioning within the system.

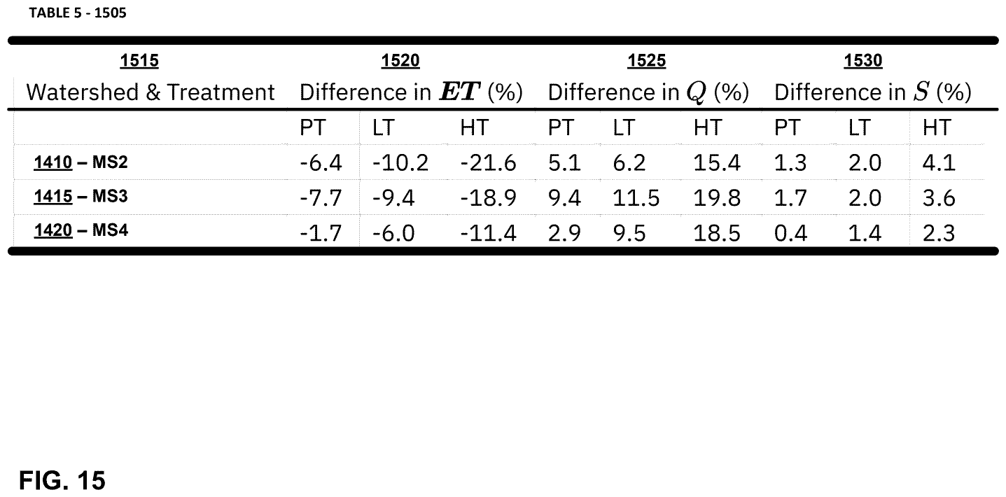

FIG. 15 presents Table 5 at element 1505, which summarizes the percent differences in annual water balance components between forest treatment scenarios, including prescribed thinning (PT), light thinning (LT), and heavy thinning (HT), and the baseline simulation for watersheds MS2, MS3, and MS4, in accordance with aspects of this disclosure. Multi-scale management area 1410 represents the management domain across hierarchical spatial scales. Trec-level management region 1415 provides data for local vegetation changes. Watershed-scale management region 1420 defines the broader simulation boundary. LiDAR derived canopy height model 1515 represents baseline canopy height. Tree polygons 1520 represent the spatial extents of individual trees or tree groups in the baseline data. Tree removal operation 1525 represents a modification to the canopy layer, reflecting vegetation management actions such as thinning or removal. Updated vegetation configuration 1530 represents the resulting data layer after tree removals have been applied. Watershed-scale management region 1420 encompasses the broader simulation area. The percent difference is computed using ((xₛ−x_{β})/x_{β})×100, where x represents the water balance variable of interest, xₛ corresponds to the thinning scenario result, and x_{β} denotes the baseline case.

After model calibration and verification of hydrologic performance, scenario-based simulations were conducted to estimate the potential impacts of forest management treatments (e.g., alternative vegetation configurations) on watershed hydrology. MS1 was not included in the scenario testing because no treatments were specified for that watershed. For MS2, MS3, and MS4, the baseline simulation served as the reference condition.

FIG. 14 previously illustrated the absolute changes in evapotranspiration (ET), streamflow (Q), and soil water storage(S) in millimeters per year. FIG. 15 complements this by presenting the corresponding percent differences relative to the baseline. In this context, S refers to the total soil water storage, including both unsaturated and saturated zone components. All values are expressed in millimeters per year, with optional conversion to acre-feet per year possible using the watershed areas provided in Table 1 (see FIG. 4).

The results depicted in FIG. 15 show consistent reductions in ET across all thinning scenarios and watersheds. These reductions are accompanied by increases in streamflow and soil water storage. The magnitude of these changes scales with the degree of thinning, with PT resulting in smaller changes and HT resulting in larger shifts in the water balance components.

Within the model framework, ET includes all simulated evaporative and transpirative processes, such as bare soil evaporation, evaporation of intercepted precipitation, sublimation from tree canopies and snowpacks, and transpiration from trees and grasses. The observed reductions in ET across treatments indicate a net decrease in atmospheric water loss, which is associated with increased streamflow and higher soil water storage as reflected in the scenario outputs.

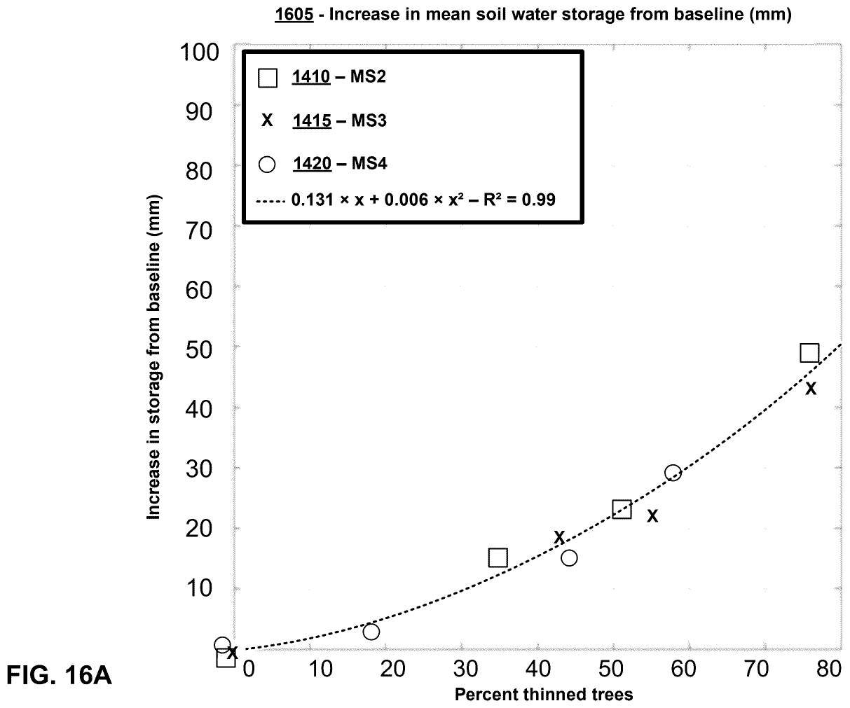

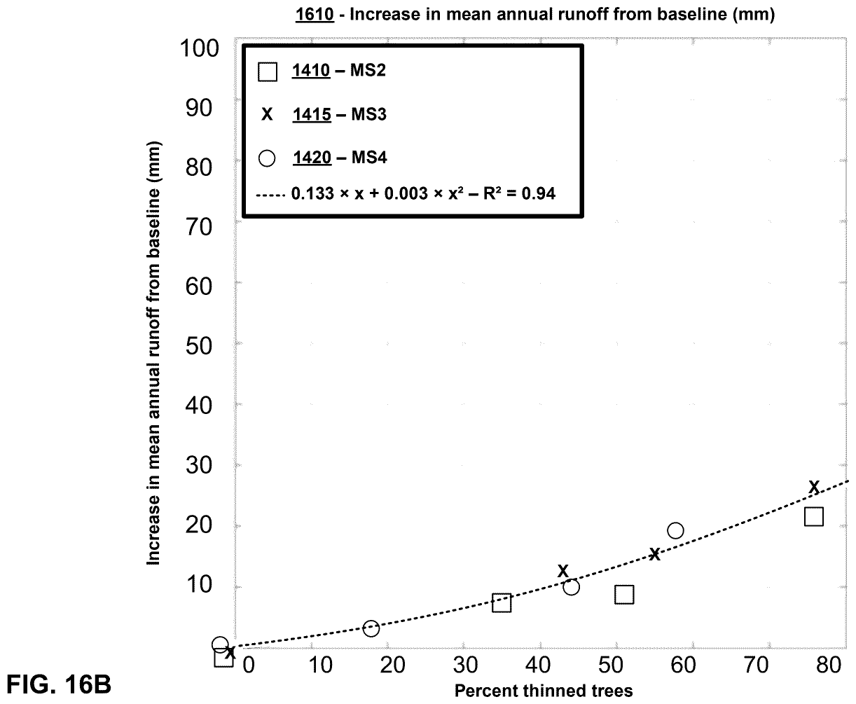

FIGS. 16A and 16B illustrate hydrologic simulation results, in accordance with aspects of this disclosure. These figures present the annual hydrologic response as a function of the percent of trees thinned, based on outputs from all simulated scenarios. The scenarios include the baseline condition, prescribed thinning (PT), light thinning (LT), and heavy thinning (HT) applied in watersheds MS2, MS3, and MS4. FIG. 16A displays the annual average increase in soil water storage (S, in millimeters) compared to the baseline simulation. Multi-scale management area 1410 represents spatial data for managing vegetation at different scales. Tree-level management region 1415 contains fine-grained vegetation data for individual tree management. Watershed-scale management region 1420 provides broader area context for environmental simulations. Hydrologic simulation input parameters 1605 are derived from the baseline vegetation and terrain data and are used to initialize environmental models for unmodified vegetation conditions. FIG. 16B displays the corresponding increase in average annual streamflow (Q, in millimeters) at the watershed outlet. Multi-scale management area 1410 represents updated spatial data reflecting vegetation management actions. Tree-level management region 1415 includes modified vegetation data for specific trees or clusters that have been altered. Watershed-scale management region 1420 provides simulation context for evaluating environmental impacts at the watershed scale. Hydrologic simulation output results 1610 include variables such as changes in streamflow, evapotranspiration, or soil water storage generated based on the modified vegetation configurations.

The relationships are captured by non-linear regressions (dashed lines) applied across all scenarios and watersheds. In FIG. 16A, the increase in soil water storage is represented by the equation:

$$0.131 \times x + 0.006 \times {x}^{2} - {R}^{2} = 0.99 .$$

In FIG. 16B, the increase in mean annual runoff is represented by the equation:

$$0.133 \times x + 0.003 \times {x}^{2} - {R}^{2} = 0.94 .$$

Here, x denotes the percent of trees thinned. These regressions assume that forest treatment levels remain constant through time.

The modeled increases in both soil water storage and streamflow scale systematically with the extent of forest thinning. As shown in FIGS. 16A and 16B, the percent of trees removed ranges from zero (no thinning, baseline condition) to approximately 75 percent (maximum thinning in MS2 and MS3 under the HT scenario). The increase in mean soil water storage relative to the baseline (FIG. 16A) exhibits a high degree of predictability, with an R² of 0.99. Similarly, the increase in mean annual runoff from the watershed outlet (FIG. 16B) is strongly correlated with thinning extent, yielding an R² of 0.94.

Second-order polynomial fits were selected for both variables due to their simplicity and their close alignment with the modeled outputs. Because these regressions incorporate data from multiple watersheds and treatment intensities, they may be generalizable to similar regions with comparable land cover, topography, and soil conditions (see FIG. 7). As a result, the mean annual values of soil water storage and streamflow can be estimated as a function of a specified thinning percentage, enabling planning and evaluation of forest management interventions at various scales.

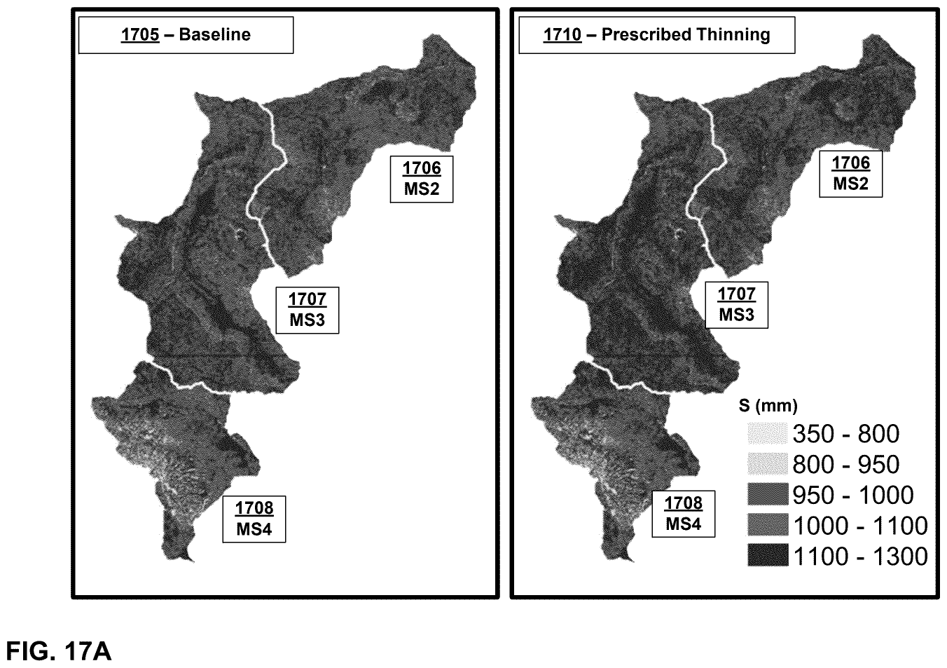

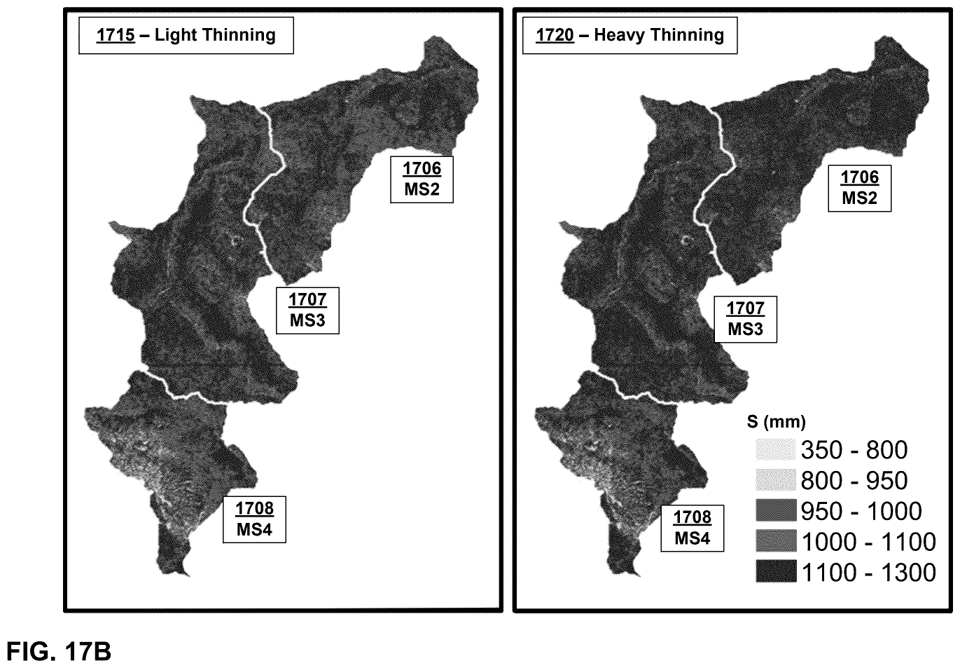

FIGS. 17A and 17B illustrate the spatial distribution of total soil water storage, denoted as S in millimeters, at the start of the water year on October 1st, averaged over the study period from 2016 to 2019, in accordance with aspects of this disclosure. Tree polygons 1705 define spatial boundaries of individual trees or groups. In FIG. 17A, canopy height model 1706, basal area raster 1707, tree removal data 1708, and vegetation data layer 1710 are shown as inputs to hydrologic simulation models. In FIG. 17B, canopy height model 1706 and basal area raster 1707 are updated to reflect vegetation management treatments (e.g., alternative vegetation configurations). Tree removal data 1708 shows post-treatment removal status. Parameter table 1715 provides numerical inputs for simulation. Geospatial vector layer 1720 contains updated vegetation configuration data for use in downstream modeling. The maps show simulated hydrologic outcomes for baseline, prescribed thinning, light thinning, and heavy thinning treatments. Three watersheds where treatments were applied are delineated by white boundary lines, while the control site remains unmodified.

The spatial distributions shown in FIGS. 17A and 17B represent general outcomes derived from distributed hydrologic modeling. Across the treated watersheds, higher values of S are evident relative to the baseline scenario. These increases in S align with the changes identified in the earlier water balance analyses. The results also reflect treatment intensity. For example, 1706-MS2, which underwent more substantial thinning, shows a larger increase in S compared to 1708-MS4, where the extent of tree removal was more limited.

The spatial maps additionally highlight intra-watershed variability. In the 1720-Heavy Thinning case, the differences in soil water storage across different locations within each watershed are less pronounced, indicating a more homogenized response to the substantial vegetation removal. By contrast, vegetation data layer 1710, representing a prescribed thinning case, preserves more spatial variation in S across the landscape. This reflects the nuanced interaction between tree removal intensity, landscape characteristics, and soil moisture retention.

Similar mapping approaches could be used to visualize other water balance components, such as evapotranspiration and its subcomponents, to further evaluate the hydrologic effects of forest management actions.

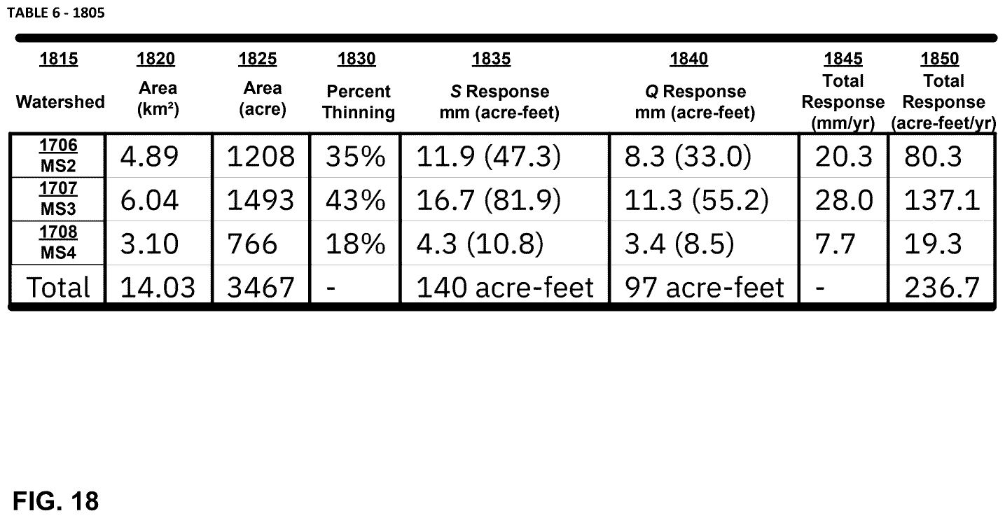

FIG. 18 illustrates Table 6 at element 1805, summarizing the estimated hydrologic response from forest thinning treatments in the three study watersheds, in accordance with aspects of this disclosure. Canopy height model 1815 represents LiDAR-derived data used in the hydrologic simulation. Tree polygons 1820 define the spatial extents of trees processed in the simulation model. Basal area raster 1825 provides tree density inputs. TIN mesh elements 1830 represent terrain surfaces for hydrologic calculations. Tree removal data 1835 identifies vegetation removals affeeting hydrologic outcomes. Streamflow model output 1840 shows predicted changes in streamflow. Soil water storage model output 1845 shows subsurface water retention. Evapotranspiration model output 1850 shows simulated changes in vegetation-driven water fluxes. The table presents the annual water balance response for prescribed thinning (PT) relative to baseline conditions (0% thinning, as described in FIGS. 16A and 16B). The reported values include average annual increases in soil water storage(S) and streamflow runoff (Q), expressed both in millimeters and acre-feet. Additionally, the total hydrologic response is provided in acre-feet per year, aggregated across MS2, MS3, and MS4.

For prescribed thinning, the percent of thinned trees varied across the watersheds: 35% in MS2, 43% in MS3, and 18% in MS4. Using the statistical relationships derived from hydrologic simulations (see FIGS. 16A and 16B), the increases in S and Q were estimated and scaled by the area of each watershed. MS2 encompasses 4.89 km² (1208 acres), MS3 covers 6.04 km² (1493 acres), and MS4 includes 3.10 km² (766 acres). The resulting hydrologic response values are summarized in FIG. 18, with each watershed contributing proportionally to the total response based on thinning level and area.

The total estimated hydrologic response from prescribed thinning is 236.7 acre-feet per year across MS2, MS3, and MS4. This value reflects the combined increases in average soil water storage and streamflow runoff due to reduced evapotranspiration, under the assumption of no understory regrowth after thinning. These results correspond to year 1 after treatment and do not account for additional ecological or hydrologic changes in subsequent years.

The underlying methodology integrates distributed hydrologic modeling with LiDAR-based forest structure data. The tRIBS (Triangulated Irregular Network-based Real-time Integrated Basin Simulator) model was employed to simulate watershed hydrology at high spatial resolution. LiDAR observations provided individual tree attributes such as height, basal area, crown diameter, and species classification, which were incorporated into the model through Voronoi-based tree segmentation. This allowed for the selective removal of trees following forest treatment prescriptions commonly implemented by the U.S. Forest Service.

Hydrologic simulations included calibration and validation against observed streamflow and snowpack records using instrumentation such as SRP Flowtography® systems. The SRP Flowtography® imagery also confirmed that hydrologic model outputs for treatment scenarios produced realistic event-level and seasonal dynamics, including transitions between low-flow and runoff conditions following forest thinning. The model successfully captured seasonal water balance dynamics, including lower streamflows in MS3 and MS4 compared to MS2 and MS1 under baseline conditions. The simulations accounted for various physical processes, such as frozen soil dynamics and snow interception, to ensure realistic representation of watershed behavior.

The statistical relationships used for FIG. 18 were developed from these continuous, high-resolution simulations. The analysis demonstrated that forest thinning tends to have a greater impact on soil water storage than on streamflow production. Hydrologic response scales with thinning intensity, while prescribed thinning provides a low-to-intermediate hydrologic benefit compared to heavier thinning scenarios. In these simulations, MS3 contributed approximately 58% of the total hydrologic response due to its larger area and higher percentage of thinned trees.

These results are intended as generalized estimates under the modeled conditions. Further modeling and field validation would be required to extrapolate findings to other regions or to consider long-term vegetation regrowth and other post-treatment dynamics. The methodology demonstrated here may be adapted for use in other ponderosa pine regions, though applying it to areas with different soil or vegetation conditions would require additional data collection, calibration, and computational assessment. Expansion of this approach to larger-scale applications would benefit from improved computational tools and enhanced decision-support systems for water resource planners.

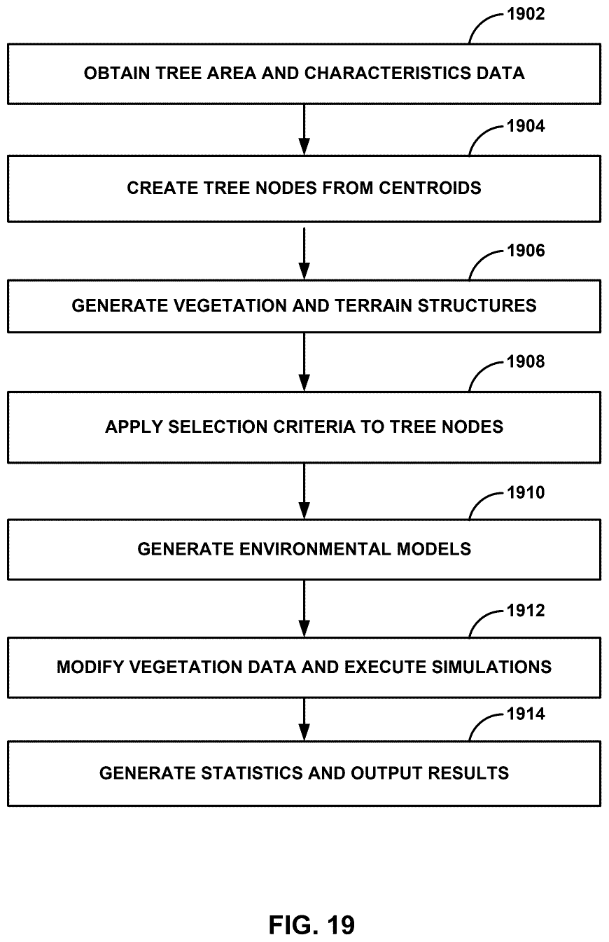

FIG. 19 is a flow diagram illustrating an example method for modeling and simulating hydrologic responses to vegetation management configurations, in accordance with aspects of this disclosure. FIG. 19 is described with respect to computing device 100, examples of processing circuitry, and environmental modeling systems configured to execute hydrologic simulations as discussed in relation to FIGS. 1-18. However, the techniques of FIG. 19 may be performed by different components of computing device 100 or by additional or alternative systems.

Processing circuitry of computing device 100 may be configured to obtain tree area and characteristics data (1902). For example, the processing circuitry may be configured to obtain input data representing tree areas for a geographic region and obtain tree characteristics for one or more tree species in the geographic region.

Processing circuitry of computing device 100 may be configured to create tree nodes from centroids (1904). For example, the processing circuitry may be configured to create tree nodes based on identified tree centroids derived from the tree areas.

Processing circuitry of computing device 100 may be configured to generate vegetation and terrain structures (1906). For example, the processing circuitry may be configured to generate spatial data structures configured to represent vegetation and terrain features based on the tree nodes and terrain data.

Processing circuitry of computing device 100 may be configured to apply selection criteria to tree nodes (1908). For example, the processing circuitry may be configured to apply selection criteria to partition the tree nodes into different management categories.

Processing circuitry of computing device 100 may be configured to generate environmental models (1910). For example, the processing circuitry may be configured to generate environmental models representing alternative vegetation configurations, including a baseline vegetation configuration and a modified vegetation configuration corresponding to tree removal treatments.

Processing circuitry of computing device 100 may be configured to modify vegetation data and execute simulations (1912). For example, the processing circuitry may be configured to modify vegetation data in the environmental models to reflect changes associated with the alternative vegetation configurations, and execute environmental simulations to compute outputs representing hydrologic or other ecological responses to the alternative vegetation configurations.

Processing circuitry of computing device 100 may be configured to generate statistics and output results (1914). For example, the processing circuitry may be configured to generate statistical relations between the vegetation management actions and the simulated environmental responses, and output data comprising one or more of: predicted outcomes, management planning information, or visualizations configured to represent changes in environmental conditions associated with the alternative vegetation configurations.

In this way, FIG. 19 illustrates an example process for using geospatial data and hydrologic modeling techniques to quantify the impact of vegetation management, such as tree thinning, on water resources. The disclosed techniques enable scalable analysis of alternative vegetation configurations for forest management planning and can be integrated with environmental simulation tools for use in diverse geographic regions.

This disclosure includes the following examples.

Example 1-A computer-implemented method comprising: obtaining input data representing tree areas for a geographic region; obtaining tree characteristics for one or more tree species in the geographic region; creating tree nodes based on identified tree centroids derived from the tree areas; generating spatial data structures configured to represent vegetation and terrain features based on the tree nodes and terrain data; applying selection criteria to partition the tree nodes into different management categories; generating environmental models representing alternative vegetation configurations, including a baseline vegetation configuration and a modified vegetation configuration corresponding to tree removal treatments; modifying vegetation data in the environmental models to reflect changes associated with the alternative vegetation configurations; executing environmental simulations to compute outputs representing ecological responses to the alternative vegetation configurations to obtain simulated environmental responses; generating statistical relations between vegetation management actions and the simulated environmental responses; and outputting data comprising one or more of: predicted outcomes, management planning information, or visualizations configured to represent changes in environmental conditions associated with the alternative vegetation configurations.

Example 2—The method of example 1, wherein generating the spatial data structures comprises generating a multi-resolution Triangulated Irregular Network (TIN) mesh configured to represent terrain and vegetation features.

Example 3—The method of example 1 or 2, wherein the TIN mesh is generated by applying constrained Delaunay triangulation to the tree nodes and terrain elevation data.

Example 4—The method of any of examples 1-3, further comprising: applying one or more selection criteria to tree characteristics, the selection criteria comprising numerical thresholds applied to one or more tree characteristics, the tree characteristics optionally including at least one of: tree height, canopy area, diameter at breast height (DBH), basal area, species type, or crown-to-height ratio.

Example 5—The method of any of examples 1-4, wherein the environmental models comprise: a first model representing the baseline vegetation configuration; and a second model representing a modified vegetation configuration corresponding to tree removal treatments.

Example 6—The method of any of examples 1-5, further comprising: modifying one or more of: vegetation rasters, vegetation parameter tables, or geospatial layers describing tree presence or absence.

Example 7—The method of any of examples 1-6, wherein executing the environmental simulations comprises executing hydrologic modeling to simulate one or more of: soil water storage, evapotranspiration, snowpack conditions, or streamflow.

Example 8—The method of any of examples 1-7, wherein executing the environmental simulations comprises executing simulation processes selected from: rain-on-snow dynamics, canopy interception, sublimation, and soil infiltration.

Example 9—The method of any of examples 1-8, further comprising: generating the statistical relations between the vegetation management actions and hydrologic responses, wherein the statistical relations optionally comprise a second-order polynomial regression relating percent tree removal to changes in soil water storage, streamflow, or evapotranspiration.

Example 10—The method of any of examples 1-9, further comprising obtaining the input data including LiDAR-derived data products to identify tree locations, generate canopy height models, or derive leaf area index (LAI) values.

Example 11—The method of any of examples 1-10, further comprising: generating visualizations comprising at least one of: spatial maps of hydrologic variables, time series plots, or statistical charts configured to depict predicted effects of the alternative vegetation configurations.

Example 12—The method of any of examples 1-11, wherein the tree areas comprise at least one of: tree polygons, tree regions, dimensions defining each of the tree areas, tree nodes pre-established within a training dataset, or sectors of a map encompassing the tree areas.

Example 13-A system comprising: processing circuitry; non-transitory computer readable media; and instructions that, when executed by the processing circuitry, configure the processing circuitry to: obtain input data representing tree areas for a geographic region; obtain tree characteristics for one or more tree species in the geographic region; create tree nodes based on identified tree centroids derived from the tree areas; generate spatial data structures configured to represent vegetation and terrain features based on the tree nodes and terrain data; apply selection criteria to partition the tree nodes into different management categories; generate environmental models representing alternative vegetation configurations, including a baseline vegetation configuration and a modified vegetation configuration corresponding to tree removal treatments; modify vegetation data in the environmental models to reflect changes associated with the alternative vegetation configurations; execute environmental simulations to compute outputs representing ecological responses to the alternative vegetation configurations to obtain simulated environmental responses; generate statistical relations between vegetation management actions and the simulated environmental responses; and output data comprising one or more of: predicted outcomes, management planning information, or visualizations configured to represent changes in environmental conditions associated with the alternative vegetation configurations.

Example 14—The system of example 13, wherein the spatial data structures comprise a multi-resolution Triangulated Irregular Network (TIN) mesh configured to represent both terrain and vegetation features.

Example 15—The system of example 13 or 14, wherein to generate the multi-resolution TIN mesh, the instructions further configure the processing circuitry to: apply constrained Delaunay triangulation to the tree nodes and terrain elevation data.

Example 16—The system of any of examples 13-15, wherein the selection criteria comprise one or more numerical thresholds applied to tree characteristics, the tree characteristics optionally including at least one of: tree height, canopy area, diameter at breast height (DBH), basal area, species type, or crown-to-height ratio.

Example 17—The system of any of examples 13-16, wherein the environmental simulations are configured to execute hydrologic modeling to simulate one or more of: soil water storage, evapotranspiration, snowpack conditions, streamflow, rain-on-snow dynamics, canopy interception, sublimation, and soil infiltration.

Example 18—The system of any of examples 13-17, wherein the instructions further configure the processing circuitry to: obtain remote sensing data comprising LiDAR-derived data products to identify tree locations, generate canopy height models, derive leaf area index (LAI) values, or some combination thereof.

Example 19—The system of any of examples 13-18, wherein the instructions further configure the processing circuitry to: generate visualizations comprising at least one of: spatial maps of hydrologic variables, time series plots, or statistical charts depicting predicted effects of the alternative vegetation configurations.

Example 20-Computer-readable storage media comprising instructions that, when executed, configure processing circuitry to: obtain input data representing tree areas for a geographic region; obtain tree characteristics for one or more tree species in the geographic region; create tree nodes based on identified tree centroids derived from the tree areas; generate spatial data structures configured to represent vegetation and terrain features based on the tree nodes and terrain data; apply selection criteria to partition the tree nodes into different management categories; generate environmental models representing alternative vegetation configurations, including a baseline vegetation configuration and a modified vegetation configuration corresponding to tree removal treatments; modify vegetation data in the environmental models to reflect changes associated with the alternative vegetation configurations; execute environmental simulations to compute outputs representing ecological responses to the alternative vegetation configurations to obtain simulated environmental responses; generate statistical relations between vegetation management actions and the simulated environmental responses; and output data comprising one or more of: predicted outcomes, management planning information, or visualizations configured to represent changes in environmental conditions associated with the alternative vegetation configurations.

Example 21-A computer program product comprising one or more instructions that, when executed by at least one processor, cause the at least one processor to perform any of the methods of examples 1-12.

Example 22-A device comprising means for performing any of the methods of examples 1-12.

For processes, apparatuses, and other examples or illustrations described herein, including in any flowcharts or flow diagrams, certain operations, acts, steps, or events included in any of the techniques described herein can be performed in a different sequence, may be added, merged, or left out altogether (e.g., not all described acts or events are necessary for the practice of the techniques). Moreover, in certain examples, operations, acts, steps, or events may be performed concurrently, e.g., through multi-threaded processing, interrupt processing, or multiple processors, rather than sequentially. Certain operations, acts, steps, or events may be performed automatically even if not specifically identified as being performed automatically. Also, certain operations, acts, steps, or events described as being performed automatically may be alternatively not performed automatically, but rather, such operations, acts, steps, or events may be, in some examples, performed in response to input or another event.

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

In accordance with the examples of this disclosure, the term “or” may be interrupted as “and/or” where context does not dictate otherwise. Additionally, while phrases such as “one or more” or “at least one” or the like may have been used in some instances but not others; those instances where such language was not used may be interpreted to have such a meaning implied where context does not dictate otherwise.

In one or more examples, the functions described may be implemented in hardware, software, firmware, or any combination thereof. If implemented in software, the functions may be stored, as one or more instructions or code, on and/or transmitted over a computer-readable medium and executed by a hardware-based processing unit. Computer-readable media may include computer-readable storage media, which corresponds to a tangible medium such as data storage media, or communication media including any medium that facilitates transfer of a computer program from one place to another (e.g., pursuant to a communication protocol). In this manner, computer-readable media generally may correspond to (1) tangible computer-readable storage media, which is non-transitory or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable medium.

By way of example, and not limitation, such computer-readable storage media can include RAM, ROM, EEPROM, CD-ROM or other optical disk storage, magnetic disk storage, or other magnetic storage devices, flash memory, or any other medium that can be used to store desired program code in the form of instructions or data structures and that can be accessed by a computer. Also, any connection is properly termed a computer-readable medium. For example, if instructions are transmitted from a website, server, or other remote source using a coaxial cable, fiber optic cable, twisted pair, digital subscriber line (DSL), or wireless technologies such as infrared, radio, and microwave, the coaxial cable, fiber optic cable, twisted pair, DSL, or wireless technologies such as infrared, radio, and microwave are included in the definition of medium. It should be understood, however, that computer-readable storage media and data storage media do not include connections, carrier waves, signals, or other transient media, but are instead directed to non-transient, tangible storage media. Disk and disc, as used, includes compact disc (CD), laser disc, optical disc, digital versatile disc (DVD), floppy disk and Blu-ray disc, where disks usually reproduce data magnetically, while discs reproduce data optically with lasers. Combinations of the above should also be included within the scope of computer-readable media.

Instructions may be executed by one or more processors, such as one or more digital signal processors (DSPs), general purpose microprocessors, application specific integrated circuits (ASICs), field programmable logic arrays (FPGAs), or other equivalent integrated or discrete logic circuitry. Accordingly, the terms “processor” or “processing circuitry” as used herein may each refer to any of the foregoing structures or any other structure suitable for implementation of the techniques described. In addition, in some examples, the functionality described may be provided within dedicated hardware and/or software modules. Also, the techniques could be fully implemented in one or more circuits or logic elements.

What is claimed is:

1. A computer-implemented method comprising:
obtaining input data representing tree areas for a geographic region;
obtaining tree characteristics for one or more tree species in the geographic region;
creating tree nodes based on identified tree centroids derived from the tree areas;
generating spatial data structures configured to represent vegetation and terrain features based on the tree nodes and terrain data;
applying selection criteria to partition the tree nodes into different management categories;
generating environmental models representing alternative vegetation configurations, including a baseline vegetation configuration and a modified vegetation configuration corresponding to tree removal treatments;
modifying vegetation data in the environmental models to reflect changes associated with the alternative vegetation configurations;
executing environmental simulations to compute outputs representing ecological responses to the alternative vegetation configurations to obtain simulated environmental responses;
generating statistical relations between vegetation management actions and the simulated environmental responses; and
outputting data comprising one or more of: predicted outcomes, management planning information, or visualizations configured to represent changes in environmental conditions associated with the alternative vegetation configurations.

2. The method of claim 1, wherein generating the spatial data structures comprises generating a multi-resolution Triangulated Irregular Network (TIN) mesh configured to represent terrain and vegetation features.

3. The method of claim 2, wherein the TIN mesh is generated by applying constrained Delaunay triangulation to the tree nodes and terrain elevation data.

4. The method of claim 1, further comprising:
applying one or more selection criteria to tree characteristics, the selection criteria comprising numerical thresholds applied to one or more tree characteristics, the tree characteristics optionally including at least one of: tree height, canopy area, diameter at breast height (DBH), basal area, species type, or crown-to-height ratio.

5. The method of claim 1, wherein the environmental models comprise:
a first model representing the baseline vegetation configuration; and
a second model representing a modified vegetation configuration corresponding to tree removal treatments.

6. The method of claim 1, further comprising:
modifying one or more of: vegetation rasters, vegetation parameter tables, or geospatial layers describing tree presence or absence.

7. The method of claim 1, wherein executing the environmental simulations comprises executing hydrologic modeling to simulate one or more of: soil water storage, evapotranspiration, snowpack conditions, or streamflow.

8. The method of claim 1, wherein executing the environmental simulations comprises executing simulation processes selected from: rain-on-snow dynamics, canopy interception, sublimation, and soil infiltration.

9. The method of claim 1, further comprising:
generating the statistical relations between the vegetation management actions and hydrologic responses, wherein the statistical relations optionally comprise a second-order polynomial regression relating percent tree removal to changes in soil water storage, streamflow, or evapotranspiration.

10. The method of claim 1, further comprising obtaining the input data including LiDAR-derived data products to identify tree locations, generate canopy height models, or derive leaf area index (LAI) values.

11. The method of claim 1, further comprising:
generating visualizations comprising at least one of: spatial maps of hydrologic variables, time series plots, or statistical charts configured to depict predicted effects of the alternative vegetation configurations.

12. The method of claim 1, wherein the tree areas comprise at least one of:
tree polygons, tree regions, dimensions defining each of the tree areas, tree nodes pre-established within a training dataset, or sectors of a map encompassing the tree areas.

13. A system comprising:
processing circuitry;
non-transitory computer readable media; and
instructions that, when executed by the processing circuitry, configure the processing circuitry to:
obtain input data representing tree areas for a geographic region;
obtain tree characteristics for one or more tree species in the geographic region;
create tree nodes based on identified tree centroids derived from the tree areas;
generate spatial data structures configured to represent vegetation and terrain features based on the tree nodes and terrain data;
apply selection criteria to partition the tree nodes into different management categories;
generate environmental models representing alternative vegetation configurations, including a baseline vegetation configuration and a modified vegetation configuration corresponding to tree removal treatments;
modify vegetation data in the environmental models to reflect changes associated with the alternative vegetation configurations;
execute environmental simulations to compute outputs representing ecological responses to the alternative vegetation configurations to obtain simulated environmental responses;
generate statistical relations between vegetation management actions and the simulated environmental responses; and
output data comprising one or more of: predicted outcomes, management planning information, or visualizations configured to represent changes in environmental conditions associated with the alternative vegetation configurations.

14. The system of claim 13, wherein the spatial data structures comprise a multi-resolution Triangulated Irregular Network (TIN) mesh configured to represent both terrain and vegetation features.

15. The system of claim 14, wherein to generate the multi-resolution TIN mesh, the instructions further configure the processing circuitry to:
apply constrained Delaunay triangulation to the tree nodes and terrain elevation data.

16. The system of claim 13, wherein the selection criteria comprise one or more numerical thresholds applied to tree characteristics, the tree characteristics optionally including at least one of: tree height, canopy area, diameter at breast height (DBH), basal area, species type, or crown-to-height ratio.

17. The system of claim 13, wherein the environmental simulations are configured to execute hydrologic modeling to simulate one or more of: soil water storage, evapotranspiration, snowpack conditions, streamflow, rain-on-snow dynamics, canopy interception, sublimation, and soil infiltration.

18. The system of claim 13, wherein the instructions further configure the processing circuitry to:
obtain remote sensing data comprising LiDAR-derived data products to identify tree locations, generate canopy height models, derive leaf area index (LAI) values, or some combination thereof.

19. The system of claim 13, wherein the instructions further configure the processing circuitry to:
generate visualizations comprising at least one of: spatial maps of hydrologic variables, time series plots, or statistical charts depicting predicted effects of the alternative vegetation configurations.

20. Computer-readable storage media comprising instructions that, when executed, configure processing circuitry to:
obtain input data representing tree areas for a geographic region;
obtain tree characteristics for one or more tree species in the geographic region;
create tree nodes based on identified tree centroids derived from the tree areas;
generate spatial data structures configured to represent vegetation and terrain features based on the tree nodes and terrain data;
apply selection criteria to partition the tree nodes into different management categories;
generate environmental models representing alternative vegetation configurations, including a baseline vegetation configuration and a modified vegetation configuration corresponding to tree removal treatments;
modify vegetation data in the environmental models to reflect changes associated with the alternative vegetation configurations;
execute environmental simulations to compute outputs representing ecological responses to the alternative vegetation configurations to obtain simulated environmental responses;
generate statistical relations between vegetation management actions and the simulated environmental responses; and
output data comprising one or more of: predicted outcomes, management planning information, or visualizations configured to represent changes in environmental conditions associated with the alternative vegetation configurations.
